(19) United States
(12) Patent Application Publication
(10) Pub. No.: US 2023/0399745 A1
(43) Pub. Date: Dec. 14, 2023

(54) METHODS AND APPARATUSES FOR FLOWABLE GAP FILL

(71) Applicant: ASM IP Holding B.V., Almere (NL)

(72) Inventors: Shinya Yoshimoto, Tokyo (JP); Makoto Igarashi, Tokyo (JP); Ranjit Borude, Tokyo (JP)

(21) Appl. No.: 18/205,766

(22) Filed: Jun. 5, 2023

Related U.S. Application Data
(60) Provisional application No. 63/366,057, filed on Jun. 8, 2022.

(51) Int. Cl. C23C 16/455; C23C 16/40; C23C 16/56; C23C 16/52; H01J 37/32; C23C 16/511; C23C 16/505

(52) U.S. Cl. CPC C23C 16/45557; C23C 16/401; C23C 16/56; C23C 16/52; H01J 37/32201; H01J 37/3244; H01J 37/32091; C23C 16/511; C23C 16/505

(57) ABSTRACT

In accordance with some embodiments herein, methods and apparatuses for flowable deposition of thin films are described. Some embodiments relate to cyclical processes for gap-fill in which deposition is followed by a microwave plasma curing treatment and repeated. In some embodiments, the deposition and microwave plasma curing treatment are carried out in separate stations. In some embodiments, a second station is heated to a higher temperature than a first station. In some embodiments, a separate module is used for high temperature curing.

### CROSS-REFERENCE TO RELATED APPLICATIONS

This application claims the benefit of priority of U.S. Provisional Patent Application No. 63/366,057, entitled “METHODS AND APPARATUSES FOR FLOWABLE GAP FILL DEPOSITION USING MICROWAVE PLASMA CURE,” filed Jun. 8, 2022, the contents of which are incorporated by reference herein in their entirety and for all purposes. Any and all applications to which a foreign or domestic priority claim is identified in Application Data Sheet as filed with the present application are hereby incorporated by reference under 37 CFR 1.57 for all purposes and for all that they contain.

### BACKGROUND

### Field

The embodiments herein are generally related to methods and apparatuses for semiconductor device manufacturing.

### Description

Integrated circuits are typically manufactured by complex, multi-step processes in which various layers of materials are sequentially constructed in a predetermined arrangement on a substrate. Thus, earlier processing steps can have significant impacts on later steps, and the effects of deviations from expected parameters (e.g., thickness, density, uniformity) can compound. Accordingly, it is important that layers be of high quality and conform to expected parameters. For example, voids, thickness non-uniformity, and other defects in a layer can cause significant problems and can reduce device yield.

### SUMMARY

For purposes of this summary, certain aspects, advantages, and novel features of the invention are described herein. It is to be understood that not all such advantages necessarily may be achieved in accordance with any particular embodiment of the invention. Thus, for example, those skilled in the art will recognize that the invention may be embodied or carried out in a manner that achieves one advantage or group of advantages as taught herein without necessarily achieving other advantages as may be taught or suggested herein.

Some embodiments are directed to A method for flowable gap-fill deposition, the method comprising: (a) placing a substrate in a first station; (b) depositing a flowable material on the substrate in the first station by a vapor deposition process at a first temperature; (c) placing the substrate in a second station; heating a surface of the substrate to a second temperature in the second station and exposing the substrate to a microwave plasma generated from a plasma gas source; and repeating (a)-(d) in a cycle until a film of desired thickness is deposited on the substrate.

In some embodiments, the first temperature is less than 300° C. In some embodiments, the second temperature is between 80° C. and 1000° C. In some embodiments, the plasma gas source comprises at least one of Ar, H₂, N₂, or NH₃. In some embodiments, the plasma comprises one or more of Ar, H₂, H, N, or H₂.

In some embodiments, the first station comprises an upper chamber and a lower chamber, and wherein the lower chamber comprises a shared intermediate space between the first station and the second station. In some embodiments, the first station and the second station comprise a shared pressure system such that the first station and the second station are maintained at a common pressure during the cycle. In some embodiments, the common pressure during the cycle is between 100 Pa and 4000 Pa.

In some embodiments, the first station comprises a first station heating unit are configured to control a temperature of the first station independently of a temperature of the second station, and wherein the second station comprises a second station heating unit configured to control the temperature of the second station independently of the first station.

In some embodiments, the film comprises a SiCN, SiN, or SiHCN film, or a combination thereof. In some embodiments, the film fills at least 90% of a gap on the surface of the substrate, at least 95% of a gap on the surface of the substrate, at least 99% of a gap on the surface of the substrate, or at least 99.5% of a gap on the surface of the substrate. In some embodiments, the substrate comprises silicon or germanium.

In some embodiments, the method further comprises introducing one or more process gasses into the first station during contacting the substrate in the first station, wherein the process gases comprise Ar, He, N₂, H₂, NH₃, O₂, or a combination of one or more of the above.

In some embodiments, the method further comprises, after a film of desired thickness is deposited on the substrate: transferring the substrate to an annealing chamber; and annealing the substrate at a third temperature, wherein the third temperature is higher than the first temperature and the second temperature.

In some embodiments, step (b) comprises depositing from about 1 nm to about 5 nm of film thickness. In some embodiments, step (b) comprises depositing from about 5 nm to about 100 nm of film thickness. In some embodiments, step (b) comprises depositing from about 1 nm to about 100 nm of film thickness.

Some embodiments herein are directed to a semiconductor processing apparatus comprising: one or more process chambers, each process chamber comprising two or more stations, each station comprising an upper compartment and a lower compartment, wherein the upper compartment is configured to contain a substrate during processing of the substrate; wherein the lower compartment comprises a shared intermediate space between the two or more stations; a first transfer system configured to move a substrate from a first process chamber to a second process chamber in a wafer handling chamber; a second transfer system configured to move the substrate from a first station to a second station within the shared intermediate space of a process chamber; a first heating unit configured to control a first station temperature independently of a second station temperature; a pressure system comprising a pump and exhaust, the pressure system configured to maintain a common process chamber pressure in the two or more stations; and a controller comprising a processor that provides instructions to the apparatus to control a cycle of: (a) placing a substrate in a first station; (b) depositing a flowable material on the substrate in the first station by a vapor deposition process at a first temperature, wherein the first temperature is less than 150° C.; (c) after depositing the flowable material on the substrate, placing the first substrate in the second station; (d) heating a surface of the substrate to a second temperature in the second station and exposing the substrate to a microwave plasma generated from a plasma gas source; and repeating (a)-(d) in a cycle until a film of desired thickness is deposited on the substrate.

Some embodiments herein are directed to a method for flowable gap-fill deposition, the method comprising: (a) placing a substrate in a first station, the first station comprising an upper chamber and a lower chamber, wherein the lower chamber comprises a shared intermediate space between the first station, a second station, a third station, and a fourth station; (b) contacting the substrate in the first station with a precursor at a first temperature, wherein the contacting with the precursor forms a first flowable film layer within a gap of the first substrate; (c) after contacting the substrate in the first station with the precursor, placing the substrate in the second station; (d) performing a first thermal and microwave plasma treatment on the substrate by heating the substrate to a second temperature in the second station and exposing the substrate to a microwave plasma generated from a plasma gas source; (e) after performing the first thermal and microwave plasma treatment on the substrate, placing the substrate in the third station; (f) contacting the substrate in the third station with the precursor at a third temperature, wherein the contacting with the precursor forms a second flowable film layer within a gap of the first substrate; (g) after contacting the substrate in the third station with the precursor, placing the substrate in the fourth station; (h) performing a second thermal and microwave plasma treatment on the substrate by heating the substrate to a fourth temperature in the fourth station and exposing the substrate to a microwave plasma generated from a plasma gas source; and repeating (a)-(h) in a cycle until a film of desired thickness is deposited on the first substrate, wherein the second temperature is different from the first temperature. In some embodiments, the third temperature is the same as the first temperature, and wherein the fourth temperature is the same as the second temperature.

In some aspects, the techniques described herein relate to a method of processing a substrate having gaps, including: providing a substrate to a reactor, forming a SiN film by supplying a silicon-containing precursor with fluidity and a nitrogen-containing gas to the reactor; and performing post-treatment for treating the SiN film, wherein post-treatment includes a first treatment step and a second treatment step.

In some aspects, the techniques described herein relate to a method, wherein the nitrogen-containing gas is activated by applying a RF power to the reactor.

In some aspects, the techniques described herein relate to a method, wherein an intensity of the RF power is about 200 W or below.

In some aspects, the techniques described herein relate to a method, wherein the nitrogen-containing gas includes at least one of N₂, N₂₀, NO₂, NH₃, NH₄, N₂H₂, N₂H₄, radicals thereof, or mixtures thereof.

In some aspects, the techniques described herein relate to a method, wherein the silicon-containing precursor includes an oligomeric precursor.

In some aspects, the techniques described herein relate to a method, wherein the silicon-containing precursor includes trimer-trisilylamine.

In some aspects, the techniques described herein relate to a method, wherein the forming the SiN film is carried out at about 100° C. or below.

In some aspects, the techniques described herein relate to a method, wherein the first treatment step and the second treatment step include at least one of thermal treatment, microwave plasma treatment, RF plasma treatment, UV treatment, VUV treatment and any combination thereof.

In some aspects, the techniques described herein relate to a method, wherein at least one of the first treatment step or the second treatment step includes a microwave plasma treatment.

In some aspects, the techniques described herein relate to a method, wherein the first treatment step includes a thermal treatment and the second treatment step includes a microwave plasma treatment.

In some aspects, the techniques described herein relate to a method, wherein the thermal treatment is carried out at about 800° C. or below.

In some aspects, the techniques described herein relate to a method, wherein an inert gas is supplied to the reactor during the thermal treatment.

In some aspects, the techniques described herein relate to a method, wherein the microwave plasma treatment is carried out at about 200° C. or below.

In some aspects, the techniques described herein relate to a method, wherein an intensity of the microwave plasma is 100 W or below.

In some aspects, the techniques described herein relate to a method, wherein a hydrogen-containing gas is supplied to the reactor during the microwave plasma treatment.

In some aspects, the techniques described herein relate to a method, wherein the hydrogen-containing gas is at least one of H₂, N₂H₂, N₂H₄, NH₃, NH₄, Na—H₂ mixing gas, or a mixture thereof.

In some aspects, the techniques described herein relate to a method, wherein a wet etch rate ratio of the SiN film is lower than 0.85.

In some aspects, the techniques described herein relate to a method, wherein the forming the SiN film, the thermal treatment, and the microwave plasma treatment are carried out ex-situ.

In some aspects, the techniques described herein relate to a method, wherein the microwave plasma is provided to the reactor remotely.

In some aspects, the techniques described herein relate to a method, wherein the method is carried out in a multi-reactor chamber, the multi-reactor chamber including a first reactor, a second reactor, and a third reactor, wherein the substrate is transferred from the first reactor to the second reactor, wherein the substrate is transferred from the second reactor to the third reactor, and wherein the forming the SiN film is carried out in the first reactor, the first treatment step is carried out in the second reactor, and the second treatment step is carried out in the third reactor.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIGS. 1 (a)-(d) illustrates several different types of gap-fill processes.

FIG. 2 (a)-(d) illustrates microscopy images of example flowable films deposited using the gap fill processes illustrated in FIG. (a)-(d).

FIGS. 2(e)-(g) illustrates microscopy images of example flowable films depositing using a gap fill process including a UV curing step.

FIG. 3 illustrates example simulated absorption spectra for different precursor materials.

FIG. 4 illustrates wet etch rate ratios for films deposited using various methods.

FIG. 5 illustrates Fourier transform infrared spectroscopy for films exposed to various levels of hydrogen RF plasma.

FIG. 6 illustrates Fourier transform infrared spectroscopy for films prepared with and without an ultraviolet curing step.

FIG. 7A illustrates a conventional apparatus for performing a deposition and subsequent anneal or cure.

FIG. 7B illustrates a multi-process chamber module and process according to some embodiments herein.

FIG. 7C illustrates a dual-chamber module and process according to some embodiments herein.

FIG. 7D illustrates a cyclic process according to some embodiments herein.

FIG. 8 illustrates a schematic drawing of a multi-process chamber module according to some embodiments herein.

FIG. 9 illustrates a top-down diagram of a multi-process chamber module according to some embodiments herein.

FIGS. 10A-10C illustrate example heating units according to some embodiments herein.

FIGS. 11A-11D illustrate example gap-fill methods according to some embodiments herein.

FIG. 12 illustrates an example multi-process chamber module with a post-annealing module according to some embodiments herein.

FIG. 13 illustrates a conventional flowable SiN gap fill process according to some embodiments herein.

FIG. 14 shows an Infrared (IR) Spectra data showing a bonding structure depending on a post-treatment according to some embodiments herein.

FIG. 15 illustrates a process flowchart for flowable SiN gap fill process according to some embodiments herein.

FIG. 16 illustrates timing graph for an exemplary flowable SiN gap fill process according to some embodiments herein.

FIG. 17 illustrates a WERR property according to a temperature to carry out a microwave plasma treatment according to some embodiments herein.

### DETAILED DESCRIPTION OF CERTAIN EMBODIMENTS

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

Certain exemplary embodiments will now be described to provide an overall understanding of the principles of the structure, function, manufacture, and use of the devices and methods disclosed herein. One or more examples of these embodiments are illustrated in the accompanying drawings. Those skilled in the art will understand that the devices and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present technology.

As used herein, the term “substrate” may refer to any underlying material or materials, including any underlying material or materials that may be modified, and/or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials or insulating materials, including, for example, silicon, silicon germanium, silicon oxide, sapphire, gallium arsenide, gallium nitride, and silicon carbide. A continuous substrate may extend beyond the bounds of a process chamber where a deposition process occurs. In some processes, the continuous substrate may move through the process chamber such that the process continues as the substrate moves, for example, until the end of the substrate is reached. A continuous substrate may be supplied from a continuous substrate feeding system to allow for manufacture and output of the continuous substrate in any appropriate form.

In semiconductor fabrication, it is often necessary to fill gaps in a substrate, for example with an insulating material. As device geometries shrink and as high aspect ratio features become common (e.g., tall features that are narrowly spaced apart, as may be seen in for example FinFET transistors and other structures), void-free filling of gaps can become increasingly difficult. The films typically deposited by existing flowable gap-fill processes have a variety of drawbacks. For example, they may exhibit poor quality and/or poor thermal stability. This may result in significant problems. For example, films may shrink by 40% or more after annealing at high temperatures (e.g., around 400° C.). Films may also etch at a rate that is higher than desired or that is unpredictable and/or unstable.

Many deposition processes have difficulty filling small trenches and other gap features used in current and emerging semiconductor processing schemes. Individual trenches and other gap-like features produced in any given technology node have principal dimensions that are significantly smaller than the critical dimensions that define the node. Thus, it is common to find gaps on a nanometer scale. Furthermore, unless the processes are highly conformal, the gaps pinch off at their necks, which can lead to the formation of voids. Furthermore, many of these gaps have relatively high aspect ratios.

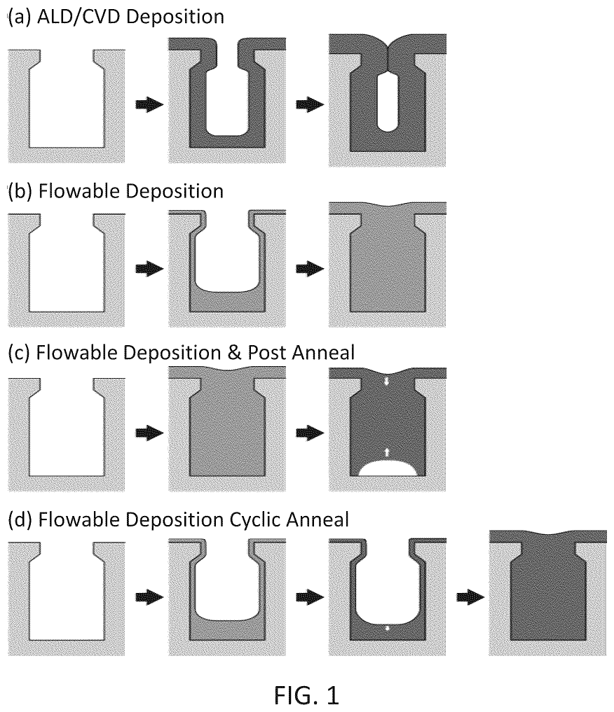

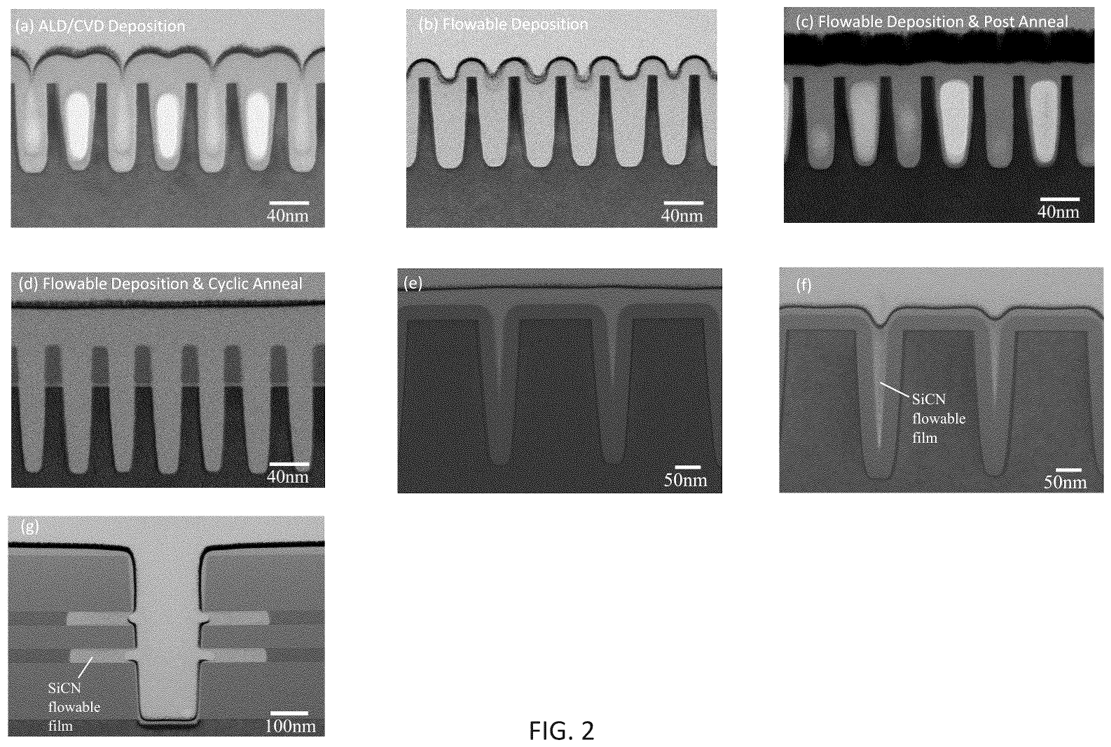

Filling gaps with fill material while avoiding voids in the fill material is challenging. Recent minimization advances in semiconductor devices, such as Self-Aligned-Contact (SAC) gap-fill in middle end of line (MEOL or MOL) processes and dummy fin gap-fill/Gate All Around (GAA) lateral processes in front end of line (FEOL) processes, require that voids and seams in gap fills be minimized and preferably eliminated. Films should preferably be of high quality such that they exhibit a high degree of etching stability and show minimal post-thermal shrinkage. Conventional chemical vapor deposition (CVD) and atomic layer deposition (ALD) of layers such as SiCN films typically results in seams and/or voids inside the gap structure. Often, it is difficult to obtain a flowable SiN or SiCN film during deposition. For example, FIG. 1A illustrates an example using ALD or CVD deposition of a thin film. As illustrated, ALD or CVD deposition may result in the formation of one or more voids in the gap. FIG. 2A illustrates a scanning transmission electron microscope (STEM) image of an example flowable SiCN film formed using ALD or CVD deposition. As shown in FIG. 2A, the SiCN film exhibits multiple voids.

One way to reduce the formation of seams or voids in SiN or SiCN film deposition in a gap is to use flowable deposition with another element such as a carbon (e.g., methyl group) or hydrogen (e.g., amine group) added in a gap-fill precursor. This method may lead to a flowable SiCN or SiN deposition with substantially no seams/voids. FIGS. 1B and 2B illustrate example void-free gap fills using a flowable deposition with carbon or hydrogen augmented precursors. However, flowable deposition processes are often performed at low temperature (e.g., 150° C. or less) to maintain precursor flowability, resulting in a lower film quality. For example, the films typically deposited by flowable gap-fill exhibit high surface variability, poor quality, and/or bad thermal stability. This can result in higher than desired wet etch rates and film shrinkage of 40% or more after annealing at increased temperatures (e.g., around 400° C.).

A post-deposition treatment may be used to achieve a high-quality flowable SiCN or SiN film. However, post-deposition treatment of substrates may lead to slower throughput. Furthermore, a single post-deposition treatment may provide limited reforming depth. For example, FIGS. 1C and 2C illustrate example flowable deposition gap-fills using a post-deposition anneal (e.g., thermal treatment). As illustrated in FIG. 1C and shown in the STEM image of FIG. 2C, a single post-deposition anneal may not form a completely void-free and seam-free gap-fill. A single thermal treatment may result in a shrinkage of the film, which may lead to void formation at the bottom of the film, as shown in FIGS. 1C and 2C.

Instead of or in addition to a post-deposition treatment, cyclic annealing may be used as illustrated in FIGS. 1D and 2D. In some embodiments, cyclic annealing may be effective to prevent film shrinkage. However, cyclic annealing may still result in films with undesirable properties such as, for example, poor surface quality.

Preferably, a deposition process results in a film with desirable bulk and surface properties. In some embodiments, treatment with an RF plasma may improve properties of the surface, but RF plasma generally does not reach to the bulk material. A thermal anneal process can impact the bulk material, but thermal annealing tends to produce only limited improvement.

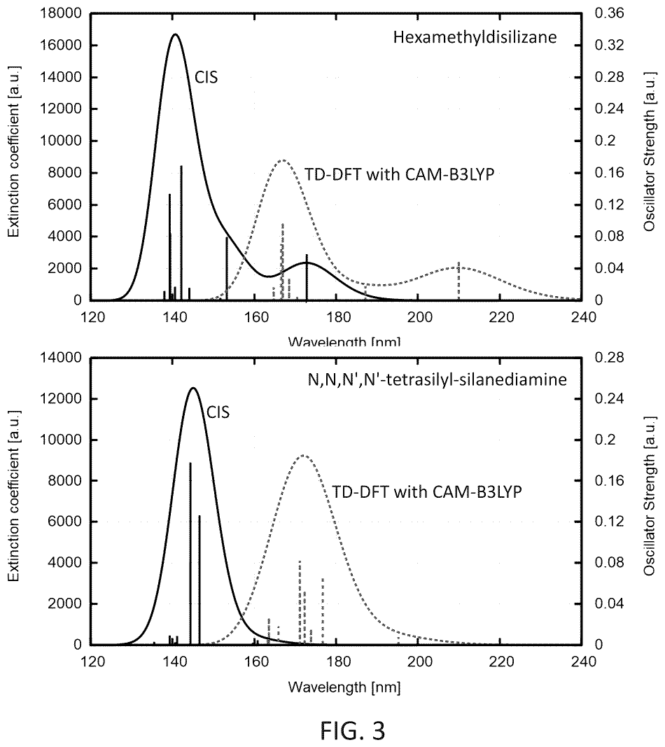

In some cases, ultraviolet curing may be used in preparing films and may result in films that are substantially free of voids and seams. For example, FIGS. 3E-3G illustrate microscopy images of SiCN films depositing using a cyclic process that includes ultraviolet curing.

As shown in FIG. 3, gap fill precursors may be sensitive to ultraviolet light. For example, hexamethyldisilazane may be used as a precursor for depositing a SiCN film, and N,N,N′,N′-tetrasilyl-silanediamine may be used for depositing a SiN film. FIG. 3 shows simulated absorption spectra calculated using the CIS method and Time-Dependent Density Functional Theory (TD-DFT) with CAM-B3LYP. CIS tends to underestimate absorption wavelengths, while TD-DFT tends to overestimate wavelength. Application of both methods to hexamethyldisilazane and N,N,N′,N′-tetrasilyl-silanediamine indicates that both absorb strongly in the ultraviolet region and thus films deposited using these (and other UV-sensitive) precursors may be impacted by exposure to ultraviolet light.

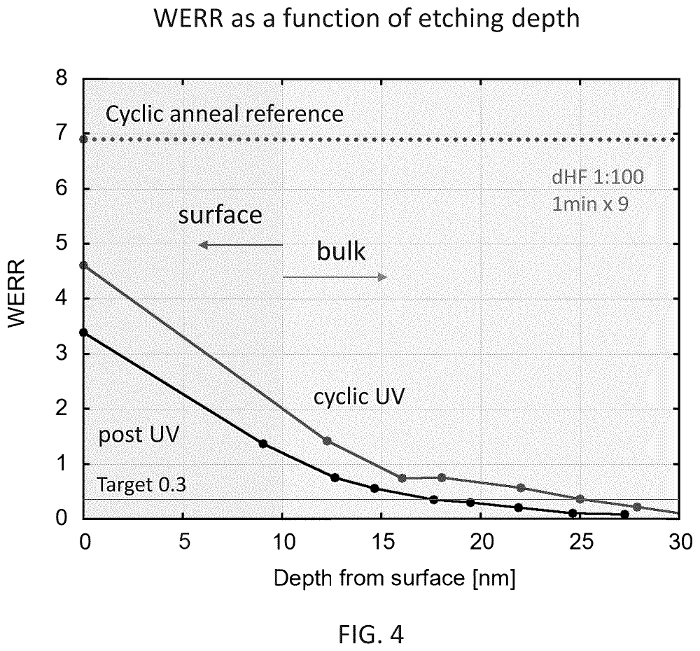

As shown in FIG. 4, exposure to ultraviolet light may significantly reduce the wet etch rate ratio (WERR) compared to films deposited using a cyclic thermal anneal. However, while the WERR is desirably decreased, the effect within the surface region of the film is limited and the WERR in the surface region is still considerably higher than the target value. The WERR can be defined as a ratio of wet etch rate of the film over the wet etch rate of thermal oxide when dipping the sample in 1:100 diluted HF (dHF) solution.

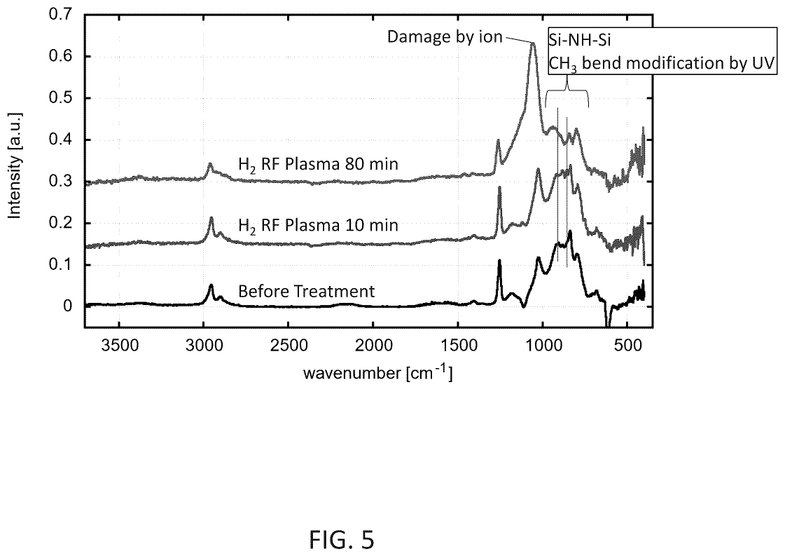

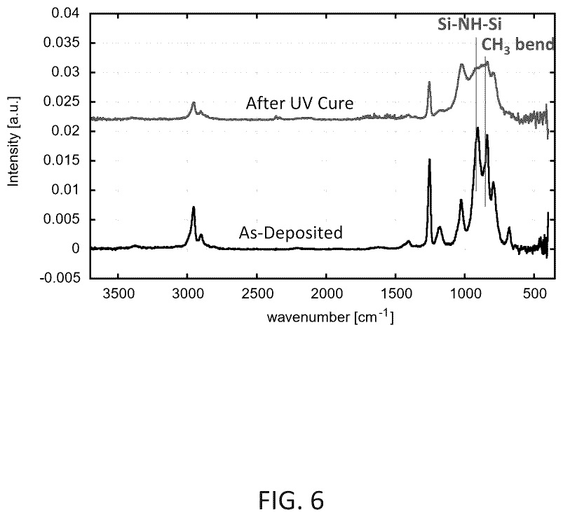

UV curing may be accomplished by exposure to a UV source such as a UV lamp. Alternatively, a film may be exposed to UV as a result of being treated with a plasma. UV emission from an RF plasma can modify Si—N and Si—C bonding, however, exposure to RF plasma can also damage the film quality and result in voids and other defects. For example, the film may oxidize after exposure to air as a result of dangling bonds. This damage may result from ions in the RF plasma having relatively high energy. FIG. 5 illustrates example Fourier Transform Infrared (FTIR) spectra showing bending vibrations for Si—NH—Si and CH₃ in deposited films. Changes in the FTIR spectra may indicate cross-linking formation or other changes The spectra show damage that can occur when a film is exposed to RF plasma. Ultraviolet light produced by the RF plasma can modify the Si—NH—Si bond and CH₃ bending, but results in significant damage from the relatively high energy ions, especially after long exposures. In comparison, exposure to UV light without an RF plasma (and thus without the high energy ions of the RF plasma) modifies the Si—NH—Si bond and CH₃ bending, but does not result in significant damage, as illustrated in FIG. 6.

Accordingly, it may be beneficial to expose a film to UV light in order to achieve improvement in the bulk properties while achieving surface improvement without an RF plasma that may damage the bulk film. As discussed in more detail below, a microwave plasma may be used instead of an RF plasma. The microwave plasma may provide relatively low energy ions compared to an RF plasma, while also emitting ultraviolet light.

### INTRODUCTION

In accordance with some embodiments herein, methods and apparatuses for flowable deposition of thin films are described. Methods and apparatuses described herein relate to filling gaps or other three-dimensional features on substrates, such as trenches, with a solid material by forming a flowing film in the gap. Some embodiments herein relate to a cyclic process including a deposition cycle comprising a flowable deposition and a treatment step that includes a microwave plasma cure. In some embodiments, the treatment step may include heating a substrate to an increased temperature relative to the deposition temperature. In some embodiments, the treatment step may be performed in a different station than the deposition. In some embodiments, the treatment step may be performed by heating a susceptor or substrate stage to a higher temperature than that used in the flowable deposition. In some embodiments, the thermal anneal may comprise a rapid thermal anneal (RTA) with an infrared (IR) treatment. In some embodiments, the cycle may be carried out in a multi-process chamber comprising one or more stations connected by a shared intermediate space.

In some embodiments, a cyclic temperature and microwave plasma cure can be used as part of the gap-fill deposition process. In some embodiments, the cyclic temperature and microwave plasma cure may comprise performing gap-fill at relatively low temperature followed by a cure at an increased temperature and exposure to a microwave plasma. In some embodiments, the cyclic gap-fill deposition process comprising a deposition cycle including the thermal and microwave plasma cure step may fill a gap without the formation of voids or seams or may reduce the formation of voids or seams relative to a process that does not use the cyclic treatment. In some embodiments, the cyclic temperature and microwave plasma cure described herein may provide improved throughput relative to post-deposition treatment processes that require movement to different, separate reaction chamber. In some embodiments, the treatment of the growing film with an increased temperature and microwave plasma curing in each deposition cycle results in improved films, for example films with fewer seams or voids relative to other processes. In some embodiments, the thermal and microwave plasma cure may improve cross-linking.

Some embodiments herein comprise using a multi-process chamber apparatus having one or more low-temperature deposition stations and one or more treatment stations. In some embodiments, a Multi-Process Quadruple-Chamber-Module (QCM) may be used, in which one or more low temperature deposition stations and one or more treatment (e.g., thermal annealing and/or microwave plasma curing) stations are used. For example, some apparatuses may comprise two deposition stations and two treatment stations. In some embodiments, some apparatuses may comprise four treatment stations, which may be configured to heat substrates to different temperatures. In some embodiments, an a-CH, SiCN, SiN, SiON, SiCO, SiCOH, SiCNH, SiCH, SiNH, or SiCON gap fill may be utilized. Thus, although the embodiments herein are primarily described in relation to SiCN and/or SiN deposition, some embodiments herein may be broadly applicable to various process chemistries.

As noted above in relation to FIGS. 1C and 2C, a single post-deposition thermal treatment may be used to achieve a relatively high quality flowable SiCN or SiN film. However, as noted above, post-deposition treatment of wafers may lead to undesirable degradation of throughput. Furthermore, a single post-deposition treatment may not be adequate because of a limited reforming depth. In some cases, a single post anneal step may result in the formation of voids in the gap fill material. Similarly, a single plasma treatment may improve film quality, but does not reach into the bulk region. Thus, a cyclic deposition process including thermal treatment (e.g., annealing) and microwave plasma curing treatment in each cycle can provide improved gap filling. In some embodiments, cyclic annealing and microwave plasma curing may be very effective to prevent or limit film shrinkage. In some embodiments, the cyclic process may be performed in a conventional reaction chamber apparatus. In some embodiments, the cyclic process may be performed in a QCM apparatus as discussed herein. In some embodiments, the thermal and microwave plasma treatments may occur simultaneously. In other embodiments, the thermal treatment may occur separately from the microwave plasma treatment, or the two may overlap and one may begin and/or end before the other.

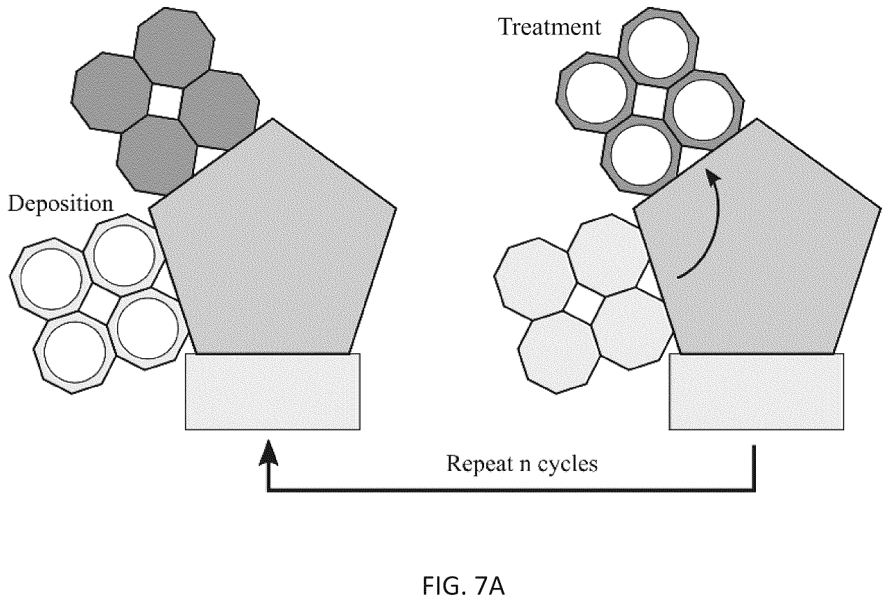

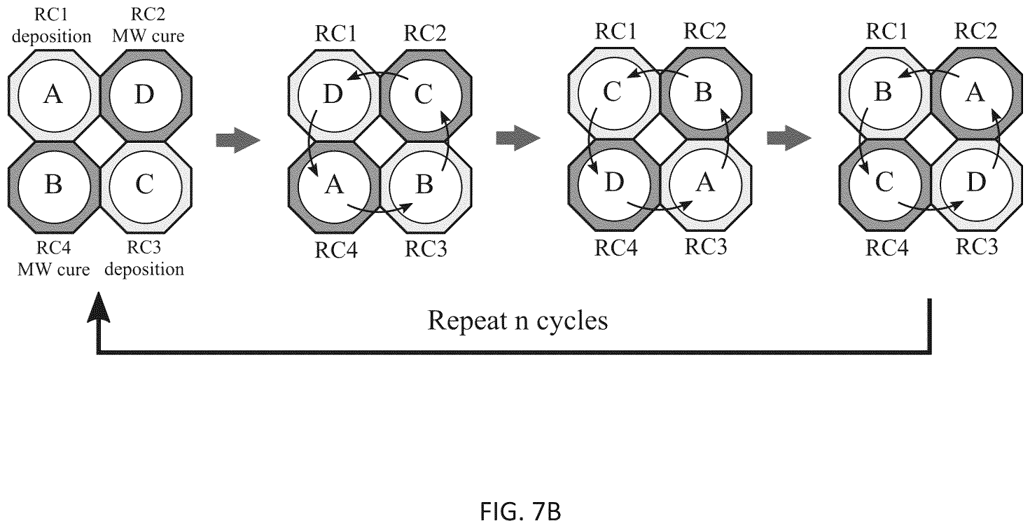

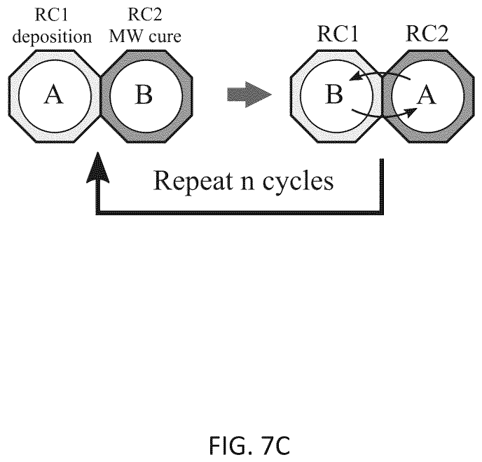

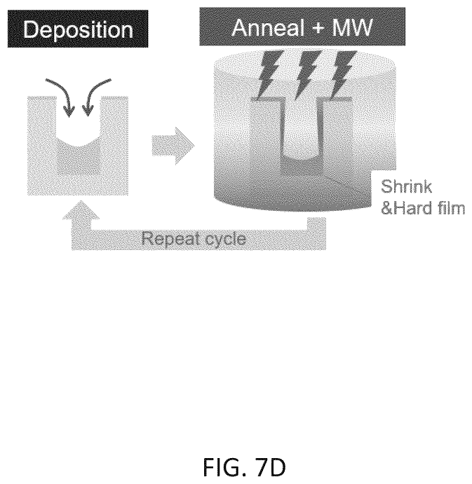

FIG. 7A illustrates a conventional apparatus for performing a deposition and subsequent treatment (e.g., thermal anneal and microwave plasma cure). As illustrated, a conventional apparatus may comprise one or more deposition chambers comprising one or more stations for performing deposition processes. The one or more deposition chambers may be separated from one or more treatment chambers via a wafer handling chamber or other transfer chamber. In the case of a typical cyclic treatment using multiple chambers, wafer transfer time between a deposition chamber and a treatment chamber through the transfer chamber can become even longer than processing times. To solve this issue, in some embodiments, a multi-process chamber module in which different processes are performed in a single chamber using separate stations can be used, and wafer transfer time may advantageously be reduced.

Thus, multi-process apparatuses having, for example, one or more low-temperature deposition stations and one or more treatment stations are described herein. In some embodiments, a cyclic process may be carried out in the stations of one chamber and a final anneal may be performed in the stations of a different chamber, for example in a different QCM.

FIG. 7B illustrates a multi-process chamber module according to some embodiments. In some embodiments, the multi-process chamber module may comprise a quad-station arrangement comprising two low-temperature deposition stations (shown as RC1 and RC3 in FIG. 7B). The remaining two stations (shown as RC2 and RC4 in FIG. 7B) may comprise treatment stations, where substrates may be thermally annealed and cured using a microwave plasma. In some embodiments, more stations may be present in a multi-process chamber module. Generally, additional stations would include at least one additional deposition station and at least one additional treatment station.

As used herein, “station” refers broadly to a location that can contain a substrate so that a process may be performed on the substrate in the station. A station can thus refer to a reactor, a portion of a reactor, or a reaction space or reaction chamber within a reactor. In some embodiments, stations in accordance with embodiments herein are in “gas isolation” from each other or are configured to be in gas isolation while a substrate is processed inside the station. In some embodiments, the stations are in gas isolation by way of physical barriers but not gas bearings or gas curtains. In some embodiments, the stations are in gas isolation by way of physical barriers in conjunction with gas bearings and gas curtains. In some embodiments, after or concurrently with the placement of a substrate in a particular station, that substrate is placed in gas isolation from the other stations (so that process steps can be performed in that station), and after the substrate has processed in the station, the station is brought out of gas isolation, and the substrate can be removed from the station and positioned in an intermediate space. Substrates from multiple different stations can be placed in a shared intermediate space for movement from station to station. The stations can be placed in gas isolation, for example, by a physical barrier. In some embodiments, the stations are not placed in gas isolation. In some embodiments, one or more stations comprise a heating and/or cooling system, so that different precursors in different stations can process substrates at different temperatures at the same time. As such, in some embodiments, an entire first station is at a lower or higher temperature than an entire second station, a first station comprises a susceptor that is at a lower or higher temperature than a susceptor in a second station, and/or a first precursor is flowed into a first station while a second precursor is flowed into a second station at a lower or higher temperature than the first station.

In some embodiments, the stations are separated from each other by solid materials, and are not separated from each other by gas bearings or gas curtains. In some embodiments, the stations are separated from each other by solid materials or gas curtains and are not separated from each other by gas bearings. In some embodiments, the stations are separated from each other by solid materials or gas bearings and are not separated from each other by gas curtains. Optionally, the physical barrier can move in conjunction with a moving stage that shuttles substrates between the stations and the intermediate space, so that the physical barrier places the station in gas isolation at the same time (or slightly before or slightly after) the substrate is placed in that station. Optionally the physical barrier can be used in conjunction with a gas barrier, for example to fill some gaps left by the physical barrier. In some embodiments, a physical barrier is provided, but a gas barrier or gas curtain is not.

In some embodiments, a station comprises a module or chamber of a reactor, so that each station comprises a separate chamber or module. In some embodiments, a station comprises a portion of a reaction chamber which can be placed in gas isolation from other portions of the reaction chamber by positioning a wall, a gas curtain, or a gas bearing between the stations. Optionally, a given station is completely enclosed by one or more walls, gas curtains, gas bearings, or a combination of any of these items. However, in some embodiments, the stations are not separated.

As illustrated in FIG. 7B, during a gap-fill process according to some embodiments herein, wafers may be rotated through the stations. For example, a wafer may enter the chamber at station RC1, at which the wafer may undergo a first flowable deposition process. In some embodiments, after undergoing the first flowable deposition process, the wafer may be transferred to RC4, as shown in FIG. 7B. Alternatively, the wafer may be transferred to RC2. In either case, the wafer may undergo a first treatment process, which may include thermal annealing, microwave plasma curing, or both. After the first treatment process, the wafer may be transferred to RC3, where it may undergo a second flowable deposition process that may be similar to or the same as the first flowable deposition process. After undergoing the second flowable deposition process, the wafer may be transferred to RC2 if it was previously transferred to RC4 or may be transferred to RC4 if it was previously transferred to RC2. In either case, the wafer may undergo a second treatment process that is similar to or the same as the first treatment process. The wafer may be transferred back to RC1 to complete a single deposition-treatment cycle. The cycle may be repeated to achieve desired film quality and thickness. Furthermore, the wafer may enter the chamber at any one of RC1, RC2, RC3, or RC4 and cycle through the stations in any direction. Generally, however, the deposition-treatment cycle will begin with at least one flowable deposition process followed by at least one treatment process. The at least one flowable deposition process may be performed simultaneously on different wafers and/or performed sequentially on a single wafer. In the illustrated embodiment of FIG. 7B, deposition stations and treatment stations of the same type are positioned diagonally. In some embodiments, this configuration may improve film uniformity. However, neighboring placement of stations of the same type is also within the scope of the embodiments disclosed herein. In some embodiments, two or more pairs of stations perform the same process on two or more substrates in parallel.

The above cyclic concept can also be applied to different numbers of stations. For example, a dual chamber module as illustrated in FIG. 7C may have a first station (RC1) for performing a low temperature flowable deposition and a second station (RC2) for performing a treatment process, and substrates may be transferred cyclically between the first station and the second station. Thus, in some embodiments, a multi-process chamber module as described herein can comprise multiple stations, half of which may be used for flowable deposition and the other half of which may be used for treatment processes. In some embodiments, a multi-process chamber module comprises at least 2 stations, for example at least 2, 3, 4, 5, 6, 7, 8, 9, 10, 11, 12, 13, 14, 15, 16, 17, 18, 19, 20, 30, 40, 50, 100, 150, 200, 250, 300, 400, or 500 stations, including ranges between any two of the listed values. However, the number of stations is not necessarily limited.

In some embodiments, all stations may be equipped with microwave plasma generators, or half of the stations may be equipped with microwave plasma generators (for example, for a cyclic process that has two steps that are repeated), or any other number of stations may be equipped with microwave plasma generators. FIG. 7D illustrates an example process according to some embodiments that could be carried out on a system having one or more stations equipped with a microwave plasma generator. A substrate may undergo a film deposition step in a first station, then be transferred to a second station to undergo annealing and microwave plasma curing treatment to shrink and harden the film. The film may be subjected to a microwave plasma treatment (e.g., a hydrogen, helium, nitrogen, or ammonia plasma) to shrink and harden the film. The microwave plasma treatment may be performed in the deposition station, in an annealing station (not shown), or in the annealing and microwave plasma curing station. The process may be repeated until a film of desired quality and thickness is formed. In some embodiments, the film may be thermally annealed to shrink and harden the film.

### Multi-Process Chamber Module

In accordance with some embodiments herein, a multi-process chamber module herein may comprise two or more stations for performing a flowable deposition and post-deposition treatment (e.g., thermal anneal and/or microwave plasma cure) of a substrate. In some embodiments, the multi-process chamber module may comprise a dual system gas-delivery and temperature control system, such that each station can be independently heated and different gases can be delivered to each station simultaneously. In some embodiments, each station of the multi-process chamber module may comprise a heater for heating the station independently from other stations of the multi-process chamber module. In some embodiments, the heater may comprise an aluminum nitride (AlN) ceramic heater or an anodized aluminum heater. In some embodiments, the heater may comprise one or more heat lamps for transmitting IR radiation to a surface of the substrate.

In some embodiments, the multi-process chamber module may comprise an integrated, single system exhaust and pump system, such that all stations can be maintained at a synchronized pressure simultaneously. Furthermore, the multi-process chamber module may comprise a single system radio frequency power source for providing radio frequency power to the stations. In some embodiments, radio frequency power may be provided independently to the stations. In some embodiments, the multi-process chamber module may comprise a single system microwave power source for providing microwave power to the stations. In some embodiments, microwave power may be provided independently to the stations. In some embodiments, the multi-process chamber module may comprise a lower chamber comprising a transfer space and an upper chamber comprising the process stations. In some embodiments, the lower chamber and the upper chamber may be unsealed. However, in some embodiments, the chambers may be sealed from each other.

Some embodiments herein provide a station for deposition that is in gas communication with a precursor source, such that a precursor can be flowed into the station. An apparatus in accordance with some embodiments herein comprises a first station and a second station. The apparatus can further comprise a controller set to control the movement of the substrate from station to station, the flow of precursors and process gases into stations, and/or the purging of stations. Different process gases can be contacted with a substrate at different temperatures that are appropriate for each particular precursor. In some embodiments, a precursor in a station is delivered via a showerhead. Optionally, the showerhead comprises a heated showerhead so as to provide the precursor to the station at a desired temperature or range of temperatures. In some embodiments, the heated showerhead provides the process gas to the station at or near the temperature at which the precursor contacts the substrate. Optionally, the showerhead comprises a vacuum exhaust scavenger around its perimeter to capture excess precursor and to minimize the amount of precursor that is potentially available to participate in CVD reactions with other gases. In some embodiments, precursors are contained within stations (and/or precursor source lines and/or purge lines) but are not permitted to enter any spaces between the stations.

In accordance with some embodiments herein, a substrate is shuffled between two or more stations, in which each station performs a deposition or treatment process. For example, a first station can provide a precursor that is adsorbed onto an exposed surface of the substrate at a first temperature, and a second station can perform a treatment (e.g., a thermal anneal and/or a microwave plasma cure) of the substrate at a second temperature different from the first temperature. The substrate can be repeatedly shuffled back and forth between the first and second stations until a substantially void-less, seam-less gap-fill is formed. In some embodiments, the substrate moves continuously between stations. In some embodiments, the motion of the substrate between stations is not continuous, but rather comprises an indexing motion, such as a stop-start, or alternating slow-fast motions.

In some embodiments, the substrate is moved from one station to the next station in the process sequence (e.g. movement time between the first station and the second station, and not necessarily including time in the station) in less than 15,000 milliseconds (msec), for example less than 10,000 msec, 9,000 msec, 8,000 msec, 7,000 msec, 6,000 msec, msec, 4,000 msec, 3,000 msec, 2,000 msec, 1,000 msec, 500 msec, 250 msec, or 100 msec, including ranges between any two of the listed values, for example 10,000-15,000 msec, 100-15,000 msec, 1,000-10,000 msec, 1,000-5,000 msec, 1,000-4,000 msec, 1,000-3,000 msec, 1,000-2,000 msec, 1,000-1,500 msec, 3,000-1,0000 msec, 3,000-5,000 msec, 3,000-4,000 msec, 100-500 msec. 100-400 msec, 100-300 msec, or 100-200 msec. Optionally, the substrate can be shuffled between two or more stations that are separated by solid materials such as walls, rather than gas bearings or gas curtains. Optionally, the substrate is shuffled between stations along a circular path or arc rather than a linear path. Optionally, the substrate is shuffled between stations along a linear path rather than an arc or circular path. It is also contemplated that moving a substrate from station-to-station without passing through any additional locations in accordance with some embodiments herein can increase throughput by minimizing handling time. Optionally, the substrate is moved directly from a first station to a second station without passing through an additional location.

It is noted that if two different stations comprise two different processes, different station conditions, for example different temperatures can be maintained in the different stations. For example, a first station can be at a first temperature optimized for a first process at the first station, and a second station can be at a second temperature optimized for a second process at the second station. As such, in some embodiments, the whole first station is at a different temperature than the whole second station. In some embodiments, the whole first station is at a different temperature than the whole second station, but the two stations are at the same pressure.

Optionally, a station is further in gas communication with a purge gas source and/or a vacuum, so that the station can be purged. For example, in accordance with some embodiments herein, after a substrate is contacted with a precursor at a first station (but before the substrate is moved to a second station), the station can be purged while the substrate remains in the first station so as to minimize or eliminate the possibility of any lingering precursor being transported to the second station along with the wafer.

Optionally, one or more stations in accordance with some embodiments herein comprise a susceptor on which a substrate can be placed. The susceptor can be heated or cooled, and thus can be configured to heat or cool a substrate to a suitable temperature. As such, in some embodiments, a susceptor in the first station is heated or cooled to a first temperature, while a susceptor in the second station is heated or cooled to a second temperature. Furthermore, in some embodiments, the susceptor can heat or cool the substrate for different durations so as to allow the substrate to reach the appropriate temperature. In some embodiments, cooling and/or heating susceptors may be necessary to maintain significant, sometimes large temperature differences between deposition stations and treatment stations. Optionally, the susceptor can have a lower mass and/or heat capacity than the substrate, so that the susceptor can be heated or cooled more rapidly than the substrate. In other embodiments, the susceptor may have a larger mass and/or heat capacity than the substrate, such that the substrate can be heated or cooled faster than the susceptor. Optionally, the susceptor does not move from station to station. Optionally, the susceptor comprises a heated and/or cooled susceptor. In some embodiments, the susceptor is at an appropriate temperature for deposition of a precursor before the substrate is placed on the susceptor. In some embodiments, the susceptor is heated to an appropriate temperature for deposition of a precursor after the substrate is placed on the susceptor.

A deposition station according to the embodiments herein may comprise a gas injection system fluidly coupled to a reaction space, a first gas source for introducing a precursor and optionally a carrier gas (e.g., He) into the reaction space, a second gas source for introducing a mixture of one or more process gasses into reaction space, an exhaust, and one or more controllers, wherein the controller(s) are configured to control gas flow into the gas injection system to carry out the methods as described herein. The controller(s) are configured to be in communication with the various power sources, heating systems, pumps, robotics, and gas flow controllers or valves of the reactor, as will be appreciated by the skilled artisan. In some embodiments, the gas injection system comprises a precursor delivery system that employs a carrier gas for carrying the precursor to the reaction space. In some embodiments, the controller may comprise a processor that provides instructions to the apparatus to control a cycle of: (a) placing a substrate in a first station; (b) contacting the substrate in the first station with a precursor at a first temperature, wherein the contacting with the precursor forms a flowable film layer within a gap of the first substrate; (c) after contacting the substrate in the first station with the precursor, placing the substrate in the second station; (d) performing a microwave plasma treatment and optionally, a thermal treatment on the first substrate by exposing the first substrate to microwave plasma and optionally heating the first substrate to a second temperature in the second station to densify the first flowable film layer. In some embodiments (a)-(d) are repeated in a cycle until a film of desired thickness is deposited on the substrate.

The apparatus can further comprise a substrate transfer system configured to place a substrate in a first station, and subsequently place the substrate in a second station after performing a first process (e.g., flowable deposition or anneal/microwave plasma cure) on the substrate in the first station. The apparatus can comprise an intermediate space or wafer transfer space. The substrate transfer system can comprise a substrate transfer member such as a spider configured to move the substrate within the intermediate space. In some embodiments, moveable barriers defining a station are moved, exposing the substrate to the intermediate space, and the transfer member transfers the substrate through the intermediate space to a different station, which may then be placed in gas isolation via moveable barriers. In some embodiments, the substrate transfer system of the apparatus comprises one or more substrate transfer mechanisms (e.g., moveable stages), in which each substrate transfer mechanism is associated with only one station and can shuttle a substrate between its station and the intermediate space. As such, a transfer mechanism for each station can move the substrate from a particular station to the intermediate space, or from the intermediate space to the station. For example, a moveable stage can raise and lower the substrate between the intermediate space, and the station associated with that particular moveable stage. In some embodiments, the substrate transfer mechanism, or stage or susceptor in the station that is configured to receive the substrate comprises a plurality of lift pins. When the lift pins are extended, a substrate sitting on the extended lift pins can be readily accessible to the substrate transfer member (e.g., spider) for pick-up or drop-off. When the lift pins are retracted, the substrate can be positioned on the appropriate surface (e.g., surface of the stage or susceptor). In the intermediate space, the substrate can be moved from one station to another, or from one substrate transfer mechanism (e.g., moveable stage) to another, for example via a rotational substrate transfer member such as a spider. Optionally, each substrate transfer mechanism (e.g., moveable stage) comprises a plurality of lift pins configured to extend and lift the substrate from the substrate transfer mechanism in the intermediate space. The lifted substrate can be readily picked up by a transfer member such as a spider to move the substrate to a different substrate transfer member in the intermediate space. Optionally, after placing a substrate in a station (e.g., on a susceptor or stage) or on a substrate transfer mechanism associated with a station, the substrate transfer member is retracted into the intermediate space.

As used herein a “substrate transfer member” or “transfer member” refers to a structure such as a rotary member or spider that can move a substrate from a first station (or from a transfer mechanism associated with the first station) to a second station (or to a transfer mechanism associated with the second station). In some embodiments, the transfer system comprises a transfer member comprising a spider. A “spider,” as used herein, refers to a wafer transfer member having multiple arms, each arm configured for engaging with a wafer through a spider end effector. The spider can be disposed centrally relative to a number of stations.

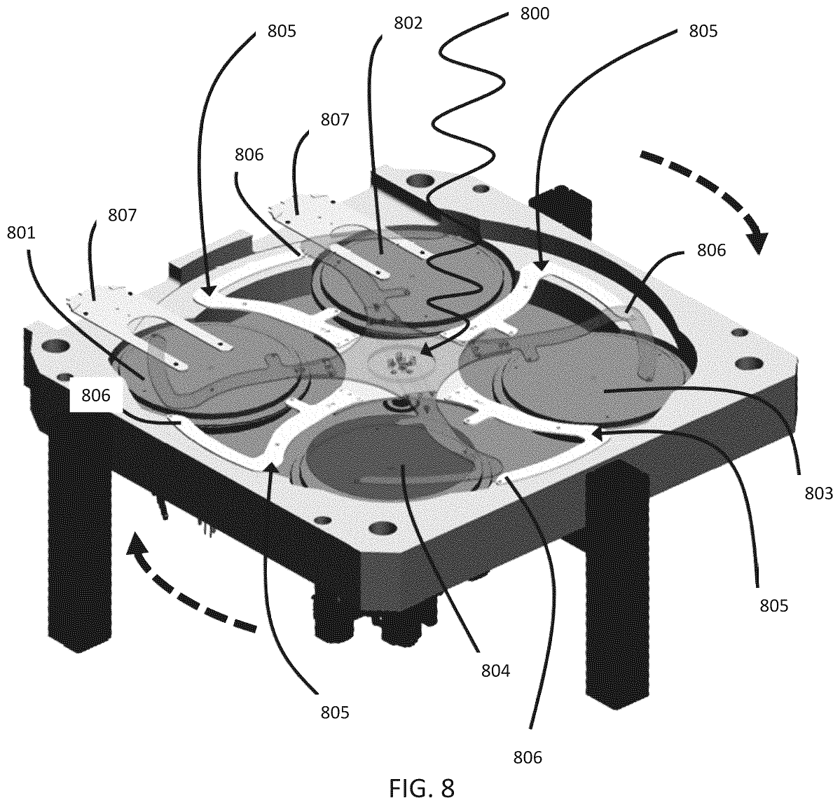

FIG. 8 illustrates a schematic drawing of a multi-process chamber module according to some embodiments herein. In some embodiments, a multi-process chamber module may comprise a spider 800 centrally disposed relative to stations 801, 802, 803, and 804. The spider 800 may have one or more arms 805, each arm provided with a spider end effector 806 for engaging a wafer. When the wafers needed to be transferred, the wafers may be elevated by lift pins or similar structures, and the spider 800 is rotated so that the spider end effectors 806 are underneath the wafer and the spider end effectors 806 engage with the wafers. In some embodiments, the spider 800 is rotated over 90 degrees (or a different value, if there is a different number of stations; for evenly distributed stations, the value can be 860 degrees divided by the number of stations), the spider end effector 806 disengages with the wafers, leaving the wafers seated on a surface (e.g. on a susceptor in a station, or on a substrate transfer mechanism as described herein), which can also comprise lift pins or similar structures for elevating the substrate. Then the spider 800 can be moved to an intermediate position, in between the stations 801, 802, 803, 804, so that when the stations are brought in gas isolation with each other, the spider nor any of its constituting parts are exposed to any of the reaction gases. Optionally, additional end effectors 807 can move the wafer out of the cluster of stations, and into a wafer handling chamber, load lock chamber, and/or another cluster of stations. In some embodiments, the wafers can be transferred in a clockwise or counterclockwise rotation between stations 801, 802, 803, 804, wherein stations 801, 802, 803, 804 comprise either flowable deposition stations or treatment stations.

In some embodiments, the substrate transfer system comprises a plurality of “substrate transfer mechanisms,” in which each substrate transfer mechanism is associated with only one station and can shuttle a substrate between a particular station and the intermediate space, for example by raising and lowering. Optionally, each substrate transfer mechanism (e.g., moveable stage) comprises a plurality of lift pins configured to extend and lift the substrate from the substrate transfer mechanism in the intermediate space. The lifted substrate can be readily picked up by a transfer member such as a spider to move the substrate to a different substrate transfer mechanism in the intermediate space. As such, each substrate transfer mechanism is exposed to no more than one station. In some embodiments, each substrate transfer mechanism comprises a moveable stage.

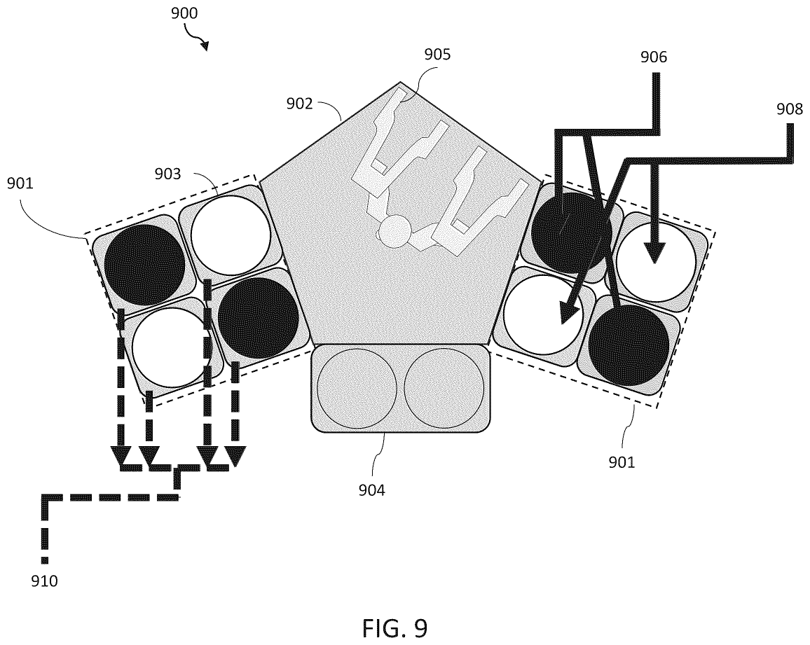

FIG. 9 illustrates a top-down diagram of a multi-process chamber module according to some embodiments herein. Each multi-process chamber module 900 may comprise one or more process chambers 901, each process chamber comprising one or more stations 903 in gas isolation from the other stations. In some embodiments, a spider 905 may move the substrate from process chamber-to-process chamber. An end effector stationed in a wafer handling chamber 902 (WHC) can add and remove substrates from the spider (in communication with the process chambers) and/or a load lock chamber 904 (LLC). As noted above, the multi-process chamber module may comprise a dual heating system comprising independent heating systems 906, 908. In some embodiments, heating system 906 may heat and/or cool one or more of the stations 903 independently from heating system 908 to a first temperature. Similarly, heating system 908 may heat and/or cool one or more of the other stations 903 independently from heating system 906 to a second temperature, different from the first temperature. This configuration enables different simultaneous processes in different stations, such as one or more deposition processes and one or more anneal processes. The multi-process chamber module 900 may also comprise a pressure system 910 comprising an exhaust and pump system. In some embodiments, the pressure system may be connected to all stations 903 in a reaction chamber 901, such that a same chamber pressure can be maintained in all of the stations 903 in the reaction chamber 901. In some embodiments, the stations 903 are not sealed from each other, such that each process space (i.e., upper chamber) is connected via an intermediate lower chamber space. In some embodiments, this lack of station separation allows for a less complex design, easier and faster wafer handling between stations, and a shared pressure system 910, such that deposition stations and anneal stations can be maintained at a same pressure simultaneously.

In some embodiments, a substrate processing apparatus comprising one or more process module(s) (PM) is provided, in which a plurality of stations is located. The stations can comprise process spaces connected by an intermediate space (i.e., lower chamber). The substrate processing equipment can comprise at least two substrate transfer systems, one for moving substrates between the load lock chamber (LLC) and the PM, and the other for moving substrates between process stations in the PM. Optionally, the PM is equipped with a capability to run at least two different processes simultaneously in stations connected by an open intermediate space by independently controlling some process conditions such as gasses and temperature, but by sharing control of other process conditions such as pressure, RF, or microwave.

In some embodiments, each station of the multi-process chamber module may comprise a heater for heating the station independently from other stations of the multi-process chamber module. In some embodiments, the heater may comprise an aluminum nitride (AlN) ceramic heater, an anodized aluminum anodized heater, and/or one or more IR heat lamps.

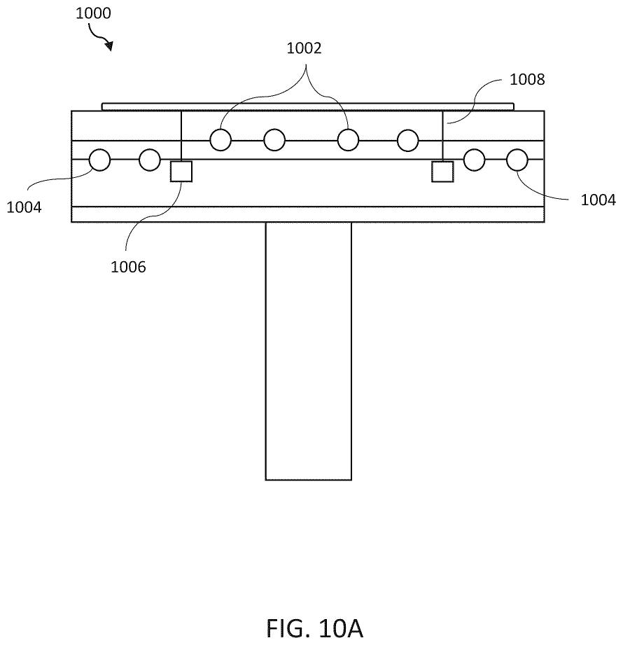

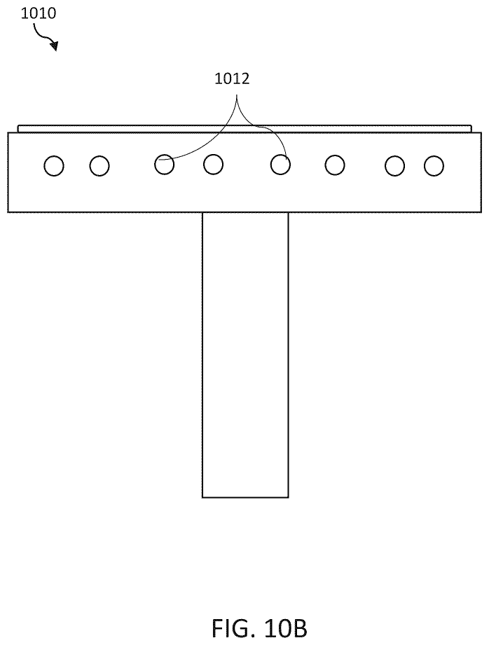

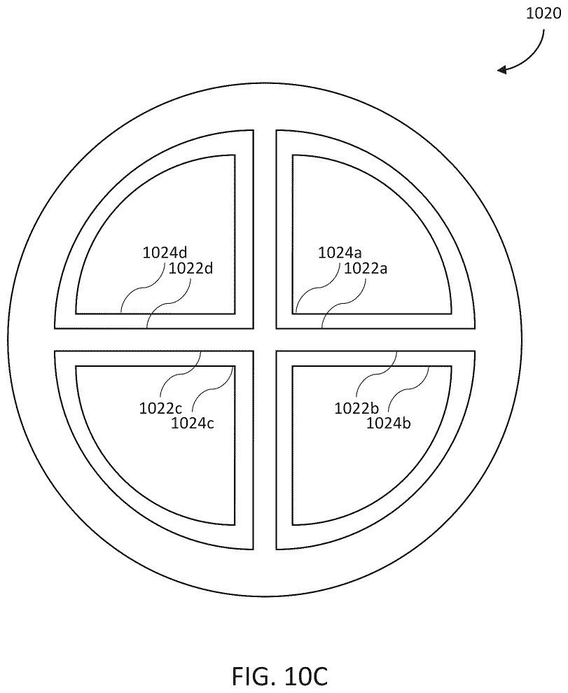

FIG. 10A illustrates an example diagram of a heating unit for use in a flowable deposition station according to some embodiments herein. The heating unit 1000 may comprise one or more heating elements 1002, 1004, in a first and second heating zone, respectively. The heating elements may be located on a surface of or within the heating unit 1000, which may be part of a susceptor for holding a substrate in a station of the multi-process chamber module. The heating elements may be powered to raise the temperature of the susceptor, substrate and/or station to a temperature suitable for flowable deposition. The heating unit 1000 may also comprise a liquid cooling line 1006 for cooling susceptor, substrate and/or station. A thermal isolation groove 1008 may be provided to improve heating and/or cooling efficiency. For example, in some embodiments, the thermal isolation groove may separate the first and second heating zones to provide uniform heating to the wafer. In some embodiments, the heating unit may be configured to heat the susceptor, substrate and/or station to a temperature between about 20° C. and about 200° C. In some embodiments, the use of two heating zones effectively prevents unfavorable wafer temperature increases by plasma heat generation or wall temperature effects.

FIG. 10B illustrates an example diagram of a heating unit for use in a treatment station according to some embodiments herein. The heating unit 1010 may comprise one or more heating elements 1012 in a single heating zone. In some embodiments, the heating unit may be configured to heat the susceptor, substrate and/or station to a temperature between about 400° C. and about 700° C.

While FIGS. 10A and 10B illustrate heating units with one heating zone or two heating zones, it will be appreciated that in some embodiments, heating units may have more than two heating zones. In some embodiments, a plurality of heating zones may be used to achieve greater temperature uniformity across a substrate, and heating zones may be able to counteract the effects of other nearby heat sources. In some embodiments, the heating zones may be configured to allow temperature to be controlled radially and/or axially. For example, in a multi-station reaction chamber, nearby heaters can make it difficult to achieve temperature uniformity. In some embodiments, the methods and apparatuses described in U.S. Patent Application No. 63/262,652, entitled “METHODS AND APPARATUSES FOR PREVENTION OF TEMPERATURE INTERACTION IN SEMICONDUCTOR PROCESSING SYSTEMS,” filed Oct. 18, 2021, which is hereby incorporated by reference in its entirety and for all purposes, may be used to improve the uniformity of substrate heating a multi-station reaction chamber. For example, the methods and apparatuses described can enable improved uniformity when there are large temperature differences between stations, for example when a first station is at 75° C. and a second, neighboring station is at 400° C., 500° C., 600° C., or even more, or any number between these numbers.

FIG. 10C illustrates an example diagram of a heating unit for use in a station according to some embodiments. The heating unit 1020 may have four heating elements 1022a-1022d and four cooling lines 1024a-1024d. As just one example, if a heating unit is deployed in a flowable deposition station that is to the left of a treatment station that is at a higher temperature, the heating unit may be configured apply more power to heating elements 1022c and 1022d relative to heating elements 1022a and 1022b, in order to achieve a more uniform temperature across the wafer while accounting for the heating effects of the nearby treatment station, and/or may apply a greater cooling flow to cooling lines 1024a and 1024b than to cooling lines 1024c and 1024d.

### Gap-Fill Methods

Various embodiments of the present disclosure relate to gap-fill methods, to structures and devices formed using such methods, and to apparatuses for performing the methods and/or for forming the structures and/or devices. Some embodiments relate to depositing flowable material in a deposition station and performing post-deposition treatment (e.g., a thermal anneal and microwave plasma cure) in a second station. In some embodiments, a deposition process comprises introducing, in a deposition station, a substrate provided with a gap, the gap comprising a recess and a lateral space extending substantially laterally from the recess, introducing a precursor into the deposition station and introducing a plasma into the deposition station, whereby the precursor reacts to form a gap-filling fluid that at least partially fills the recess and the lateral space of the gap. In some embodiments, the deposition may comprise introducing one or more process gases in addition to the precursor into the deposition station. In some embodiments, another vapor phase process may be used to deposit a flowable material.

Gap-fill methods that deposit flowable materials often operate by flowing precursor molecules in a gaseous phase. The gaseous phase precursors may be formed into polymers by striking a plasma in a chamber filled with a volatile precursor that can be polymerized within certain process parameters. In some embodiments, the precursor may be selected from a list consisting of silylamines, silazanes, cyclosilazanes, and silicon alkylamines. Optionally, the gas phase can comprise a further gas apart from the plasma, for example a noble gas, hydrogen, a carrier gas, a dilution gas, and so forth. Process parameters can include, for example, partial pressure of a precursor during a plasma strike and wafer temperature. As used herein, polymerization can include the formation of longer molecules and need not necessarily include a carbon-carbon bond. Indeed, polymerization can include the formation of, for example, Si—Si bonds, Si—C bonds, and/or Si—N bonds. In some embodiments, the viscous material forms a viscous phase and can flow into a trench on the substrate which may be, for example, a silicon wafer. As a result, the viscous material may seamlessly fill the trench in a bottom-up manner. The formed polymers may be in a liquid phase and may flow (e.g., by capillary action) into gaps. Subsequent processing steps may be used to solidify the polymer. Typically, a curing step is used to harden the film.

Flowable films may be temporarily obtained when the volatile precursor is polymerized by a plasma and deposited on a surface of a substrate, wherein gaseous precursor (e.g., monomer) is activated or fragmented by energy provided by plasma gas discharge, thereby initiating polymerization, and when the resultant material is deposited on the surface of the substrate, the material shows temporarily flowable behavior. The film quality of the material deposited on the surface can be improved via a cyclic process including thermal treatment and microwave plasma curing as described herein.

In some embodiments, a volatile precursor can be polymerized within a certain parameter range mainly defined by partial pressure of the precursor during a plasma strike, wafer temperature, and total pressure in the reaction chamber. In order to adjust the “precursor partial pressure,” an indirect process knob (e.g., dilution gas flow) may be used to control the precursor partial pressure. The absolute number of the precursor partial pressure may not be required to control flowability of a deposited film. Instead, a ratio of the flow rate of the precursor to the flow rate of the remaining gas and the total pressure in the reaction space at a reference temperature can be used as practical control parameters.

A gap in a substrate may refer to a patterned recess or trench in a substrate. Accordingly, exemplary methods of filling a patterned recess or trench on a substrate include providing a substrate comprising the recess/trench in a reaction space, providing a precursor to the reaction space, thereby filling the recess with the precursor, and providing a plasma to form a viscous phase of the precursor in the recess, wherein the viscous phase of the precursor flows and deposits or forms deposited material in the bottom portion of the recess relative to sidewalls and/or a top portion of the substrate away from the recess.

In some embodiments, gap-filling deposition methods include the use of a radio frequency (RF) plasma and pulsed precursor flow. In some embodiments, process parameters may be changed to achieve high enough partial pressure during the entire RF-on period for polymerization to progress, and to provide sufficient energy to activate the reaction (defined by the RF-on period and RF power). In some embodiments, temperature and pressure may be controlled for polymerization/chain growth and set above the melting point and below the boiling point of the flowable phase. In some embodiments, the process of filling a gap with a gap filling fluid comprises one or more of the following sub-steps. A substrate comprising the gap is positioned in a deposition station. The gap comprises a recess in fluid connection with one or more lateral spaces. In some embodiments, a precursor may be introduced into the deposition station. In some embodiments, one or more process gases may also be introduced into the deposition station. The process gasses may comprise one or more further gases including a co-reactant. In some embodiments, a plasma, such as an RF plasma, may be maintained in the deposition station. In some embodiments, the precursor may be reacted to form a gap filling fluid on the substrate. In some embodiments, the gap filling fluid may at least partially fill the plurality of recesses and the one or more lateral spaces. In some embodiments, the process gases and the precursor may be introduced simultaneously. In some embodiments, the precursor may be introduced before or after the process gases. In some embodiments, the RF plasma may be maintained before, during, or after introduction of the precursor and/or process gases. It will be understood by those skilled in the art that when the methods described above are carried out in a sequential manner, i.e., cyclically, a small amount of material may be deposited each cycle and the sequence of steps may be repeated until a layer with a desired thickness is obtained. In some embodiments, the process is carried out cyclically and one or more steps are separated by purge gas pulses.

In some embodiments, the above methods involve providing the precursor intermittently to the deposition station, and continuously applying a plasma. In some embodiments, the above methods involve providing the precursor intermittently to the deposition station, and intermittently applying a plasma. The latter embodiments thus feature the sequential application of precursor pulses and plasma pulses to the reaction space.

In some embodiments, process gasses may comprise, for example, Ar, He, N₂, H₂, NH₃, O₂, or a combination of one or more of the above. In some embodiments, precursors may only be introduced into deposition stations. In other words, deposition stations and treatment stations may comprise separated precursor gas connections.

Without being bound by theory or any particular mode of operation, it is believed that the depositing material desirably remains viscous or liquid throughout the deposition process and should not readily solidify or evaporate. It is further believed that under desirable reaction conditions, the vapor pressure of the liquid phase, but not that of the precursor, should be lower than total station pressure. Thus, it is believed that station temperature and pressure should be maintained at conditions under which the flowable reaction products exist as a liquid, and the precursor exists as a gas.

In some embodiments, the station pressure may be maintained at a pressure between around 100 Pa to 4000 Pa. For example, the station pressure may be maintained at about 100 Pa, about 150 Pa, about 200 Pa, about 250 Pa, about 300 Pa, about 350 Pa, about 400 Pa, about 450 Pa, about 500 Pa, about 550 Pa, about 600 Pa, about 650 Pa, about 700 Pa, about 750 Pa, about 800 Pa, about 850 Pa, about 900 Pa, about 950 Pa, about 1000 Pa, about 1050 Pa, about 1100 Pa, about 1150 Pa, about 1200 Pa, about 1250 Pa, about 1300 Pa, about 1350 Pa, about 1400 Pa, about 1450 Pa, about 1500 Pa, about 1550 Pa, about 1600 Pa, about 1650 Pa, about 1700 Pa, about 1750 Pa, about 1800 Pa, about 1850 Pa, about 1900 Pa, about 1950 Pa, about 2000 Pa, about 2050 Pa, about 2100 Pa, about 2150 Pa, about 2200 Pa, about 2250 Pa, about 2300 Pa, about 2350 Pa, about 2400 Pa, about 2450 Pa, about 2500 Pa, about 2550 Pa, about 2600 Pa, about 2650 Pa, about 2700 Pa, about 2750 Pa, about 2800 Pa, about 2850 Pa, about 2900 Pa, about 2950 Pa, about 3000 Pa, about 3050 Pa, about 3100 Pa, about 3150 Pa, about 3200 Pa, about 3250 Pa, about 3300 Pa, about 3350 Pa, about 3400 Pa, about 3450 Pa, about 3500 Pa, about 3550 Pa, about 3600 Pa, about 3650 Pa, about 3700 Pa, about 3750 Pa, about 3800 Pa, about 3850 Pa, about 3900 Pa, about 3950 Pa, about 4000 Pa, or any value between any of the aforementioned values.

In some embodiments, the deposition station temperature may be maintained at a temperature lower than about 300° C. For example, the station temperature may be maintained via a heating/cooling system at about 50° C., about 55° C., about 60° C., about about 70° C., about 75° C., about 80° C., about 85° C., about 90° C., about 95° C., about 100° C., about 105° C., about 110° C., about 115° C., about 120° C., about 125° C., about 130° C., about 135° C., about 140° C., about 145° C., about 150° C., about 155° C., about 160° C., about 165° C., about 170° C., about 175° C., about 180° C., about 185° C., about 190° C., about 195° C., about 200° C., about 205° C., about 210° C., about 215° C., about 220° C., about 225° C., about 230° C., about 235° C., about 240° C., about 245° C., about 250° C., about 255° C., about 260° C., about 265° C., about 270° C., about 275° C., about 280° C., about 285° C., about 290° C., about 295° C., about 300° C., or any value between the aforementioned values.

In some embodiments, RF power may be provided to the station that is between about 20 W and 1000 W. For example, in some embodiments, RF power may be provided to the station at about 20 W, about 40 W, about 60 W, about 80 W, about 100 W, about 120 W, about 140 W, about 160 W, about 180 W, about 200 W, about 220 W, about 240 W, about 260 W, about 280 W, about 300 W, about 320 W, about 340 W, about 360 W, about 380 W, about 400 W, about 420 W, about 440 W, about 460 W, about 480 W, about 500 W, about 520 W, about 540 W, about 560 W, about 580 W, about 600 W, about 620 W, about 640 W, about 660 W, about 680 W, about 700 W, about 720 W, about 740 W, about 760 W, about 780 W, about 800 W, about 820 W, about 840 W, about 860 W, about 880 W, about 900 W, about 920 W, about 940 W, about 960 W, about 980 W, about 1000 W, or any value between the aforementioned values.

In some embodiments, a film having a thickness of at least about 1 nm is deposited per cycle, for example about 1 nm, about 2 nm, about 3 nm, about 4 nm, about 5 nm, about 6 nm, about 7 nm, about 8 nm, about 9 nm, about 10 nm, about 15 nm, about 20 nm, about 25 nm, about 30 nm, about 35 nm, about 40 nm, about 45 nm, about 50 nm, about 60 nm, about 70 nm, about 80 nm, about 90 nm, or about 100 nm, including ranges between any two of the listed values, for example 1 nm-100 nm, 1 nm-20 nm, 1 nm-10 nm, 1 nm-5 nm, 2 nm-100 nm, 2 nm-20 nm, 2 nm-10 nm, 2 nm-5 nm, 3-4 nm, 5 nm-100 nm, 5 nm-20 nm, 5 nm-10 nm, 10 nm-100 nm, or 10 nm-20 nm.

Precursors and process gases may be provided to the stations at a volumetric flow rate of around 0.1 standard liter per minute (SLM) to about 10 SLM. For example, precursors and process gases may be provided to the stations at a volumetric flow rate of about SLM, about 0.5 SLM, about 1 SLM, about 1.5 SLM, about 2 SLM, about 2.5 SLM, about 3 SLM, about 3.5 SLM, about 4 SLM, about 4.5 SLM, about 5 SLM, about 5.5 SLM, about 6 SLM, about 6.5 SLM, about 7 SLM, about 7.5 SLM, about 8 SLM, about 8.5 SLM, about 9 SLM, about 9.5 SLM, about 10 SLM, about 10.5 SLM, about 11 SLM, about 11.5 SLM, about 12 SLM, about 12.5 SLM, about 13 SLM, about 13.5 SLM, about 14 SLM, about 14.5 SLM, about 15 SLM, about 15.5 SLM, about 16 SLM, about 16.5 SLM, about 17 SLM, about 17.5 SLM, about 18 SLM, about 18.5 SLM, about 19 SLM, about 19.5 SLM, about 20 SLM, or any value in between the aforementioned values.

In some embodiments, the substrate comprises a semiconductor. In some embodiments, the semiconductor comprises silicon. Further provided herein is a structure comprising a semiconductor substrate comprising a plurality of recesses. The plurality of recesses is in fluid connection with one or more lateral spaces. Also, the plurality of recesses and the one or more lateral spaces are at least partially filled with a gap filling fluid upon completion of one or more deposition cycles. In some embodiments, the gap filling fluid completely fills at least 90%, preferably at least 95%, more preferably at least 99%, most preferably all of the plurality of recesses. In some embodiments, the gap filling fluid completely fills at least 90%, preferably at least 95%, more preferably at least 99%, most preferably all of the lateral spaces. In other words, the gap filling fluid preferably fills the entirety of each lateral space that is to be filled with gap filling fluid. In some embodiments, the gap filling fluid is substantially free of voids or seams.

In some embodiments, after deposition and/or the cyclic thermal anneal/microwave plasma cure, the substrate may undergo an NF₃ and O₂ cleaning process. In some embodiments, a final plasma curing step may also be employed to further improve the gap-fill film quality. In some embodiments, the final plasma curing step may employ a continuous direct plasma. Gap filling fluid deposition and direct plasma curing may be carried out cyclically. In some embodiments, this allows efficiently curing all, or at least a large portion, of the gap filling fluid. In some embodiments, the plasma curing step may involve the use of a micro-pulsed plasma. In some embodiments, the plasma curing step may be carried out cyclically, i.e., alternating cycles of gap filling fluid deposition and microwave plasma are employed, though a post-deposition plasma curing treatment is possible as well. The application of cyclic gap filling fluid deposition and plasma steps allows efficiently curing all, or at least a large portion, of the gap filling fluid.

In some embodiments, a cyclical gap-fill process may comprise performing a deposition step in a deposition station, performing a thermal anneal and/or microwave plasma curing step in a treatment station, and optionally repeating the deposition step and the thermal and/or microwave plasma treatment step until a film of desired thickness and quality is formed on a substrate. The cycle of deposition-treatment may be performed n times, wherein n is an integer. In some embodiments, after completion of one instance of a flowable deposition step, a wafer may be transferred to a separate treatment station, where the wafer may undergo a thermal anneal and/or microwave plasma cure step. The thermal and microwave plasma treatment provided by the treatment stations may improve flowable film quality of, for example, SiCN or SiN films. In some embodiments, the cyclic anneal and microwave plasma treatment may comprise a heat treatment, including a thermal cure using He, Ar, Na, H₂, O₂, NH₃, or any combination of the aforementioned, followed by a wafer cleaning process using NF₃ and O₂. During the cyclic anneal, the wafer may be heated to a temperature between about 80° C. and about 700° C. For example, the wafer may be heated to a temperature between about 80° C., about 90° C., about 100° C., about 110° C., about 120° C., about 130° C., about 140° C., about 150° C., about 160° C., about 170° C., about 180° C., about 190° C., about 200° C., about 210° C., about 220° C., about 230° C., about 240° C., about 250° C., about 260° C., about 270° C., about 280° C., about 290° C., 300° C., about 310° C., about 320° C., about 330° C., about 340° C., about 350° C., about 360° C., about 370° C., about 380° C., about 390° C., about 400° C., about 410° C., about 420° C., about 430° C., about 440° C., about 450° C., about 460° C., about 470° C., about 480° C., about 490° C., about 500° C., about 510° C., about 520° C., about 530° C., about 540° C., about 550° C., about 560° C., about 570° C., about 580° C., about 590° C., about 600° C., about 610° C., about 620° C., about 630° C., about 640° C., about 650° C., or any value between the aforementioned vales. Similar pressure and gas conditions as those in the deposition chamber can be used to perform deposition and annealing simultaneously.

A microwave plasma curing process may be carried out using a variety of plasma gas sources as depicted in

Table 1, which shows the UV emission wavelengths for various plasma species in a range of 100 nm to 230 nm. For example, Ar, H₂, and N₂ microwave plasmas may be used as sources for ultraviolet light in the absorption range of common precursors for SiCN, SiN, and other gap fill films. In some embodiments, an NH₃ microwave plasma may be used and may emit in the UV spectrum via the emission from H and H₂ species. While an He microwave plasma emits in the UV spectrum, its emission at 58 nm (21.4 eV) may be too high for use modifying a film such as SiCN or SiN or other gap fill materials.

TABLE 1
Microwave Plasma Materials

| Plasma Gas Source | Plasma Species | UV Emission (nm) |
|---|---|---|
| Ar | Ar | 105, 107 |
| H₂ | H₂ | 150-170 |
| | H | 103, 122 |
| He | He | — |
| N₂ | N₂ | — |
| | N | 107-124, 133, 141, 150, 174 |

### Table 1: Microwave Plasma Materials

In some embodiments, microwave power provided to the station may be between about 500 W and about 10,000 W. For example, in some embodiments, microwave power can be provided to the station at about 500 W, about 600 W, about 700 W, about 800 W, about 900 W, about 1000 W, about 1250 W, about 1500 W, about 1750 W, about 2000 W, about 2250 W, about 2500 W, about 3000, about 3500 W, about 4000 W, about 4500 W, about 5000 W, about 5500 W, about 6000 W, about 6500 W, about 7000 W, about 7500 W, about 8000 W, about 8500 W, about 9000 W, about 9500 W, about 10,000 W, or any value between the aforementioned values.

In some embodiments, a microwave plasma exposure time may be between about 5 s and about 1800 s. For example, in some embodiments, the microwave plasma exposure time can be about 5 sec, about 10 sec, about 20 sec, about 30 sec, about 60 sec, about 120 sec, about 180 sec, about 240 sec, about 300 sec, about 360 sec, about 420 sec, about 480 sec, about 540 sec, about 600 sec, about 660 sec, about 720 sec, about 780 sec, about 840 sec, about 900 sec, about 960 sec, about 1020 sec, about 1080 sec, about 1140 sec, about 1200 sec, about 1260 sec, about 1320 sec, about 1380 sec, about 1440 sec, about 1500 sec, about 1560 sec, about 1620 sec, about 1680 sec, about 1740 sec, about 1800 sec, or any value between the aforementioned values.

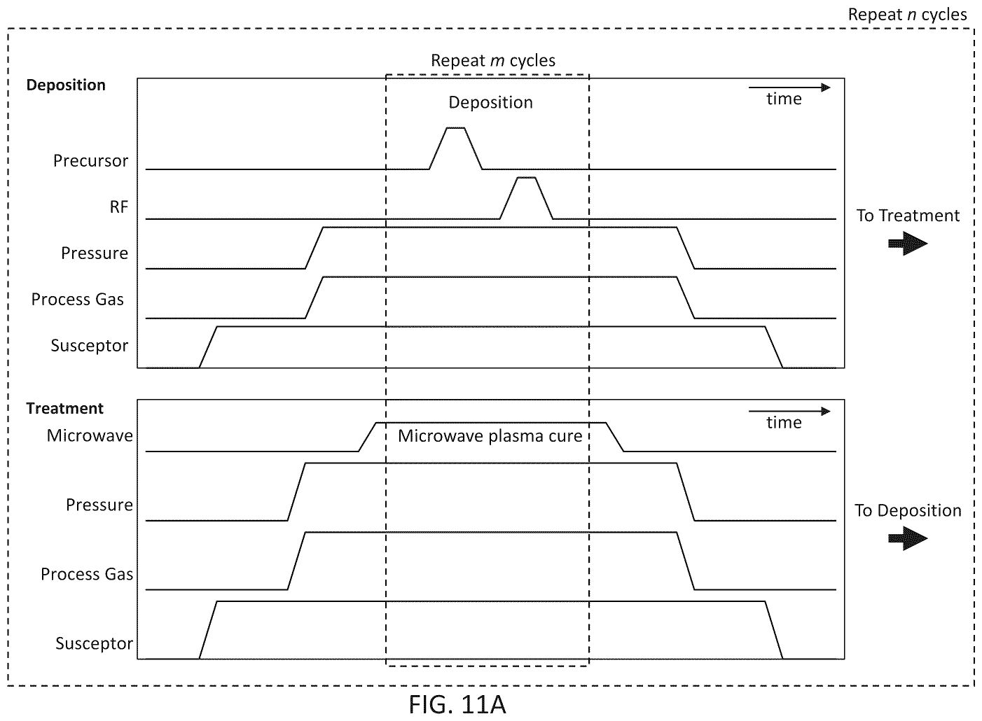

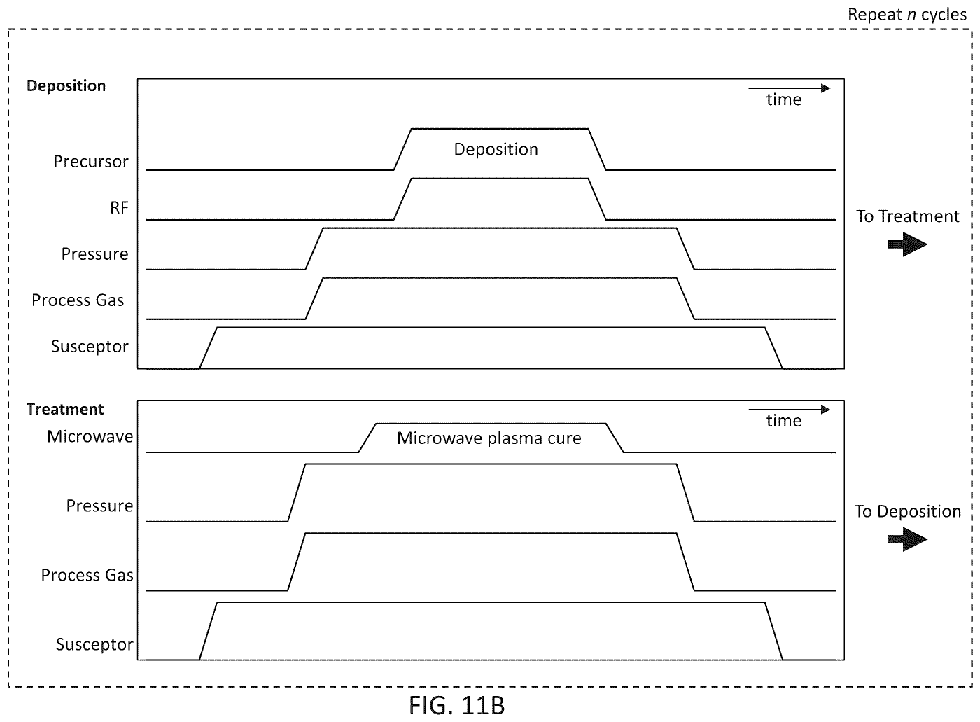

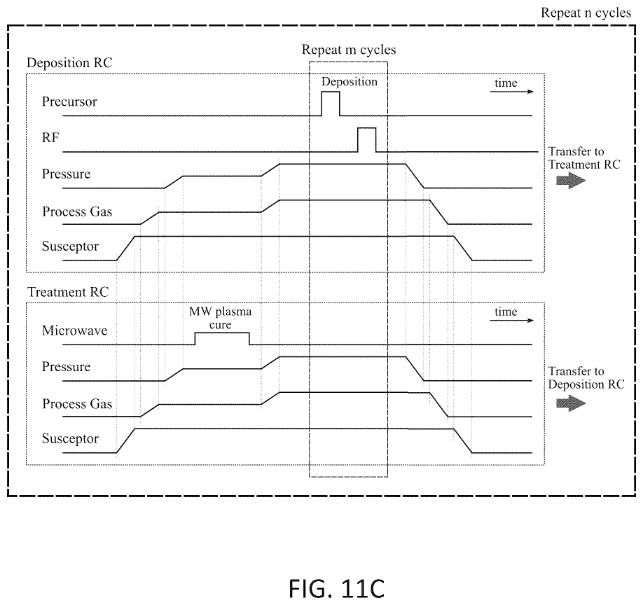

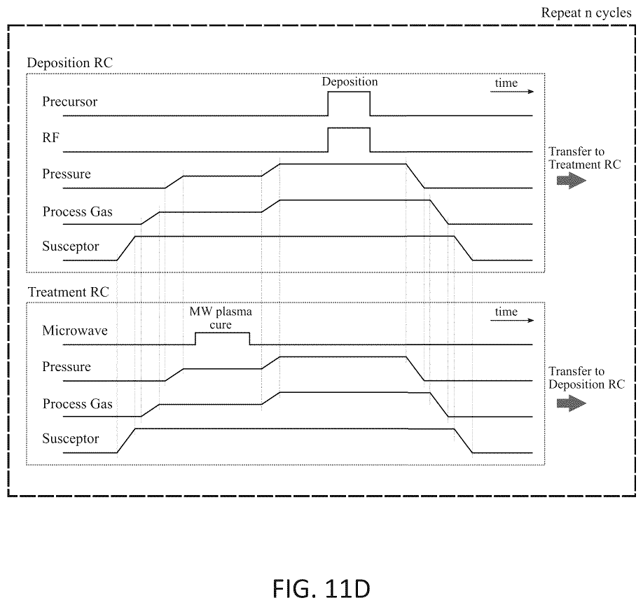

FIGS. 11A-11D illustrate example embodiments of gap-fill methods. FIG. 11A illustrates an example gap-fill method using repeated cycle of vapor deposition, such as ALD, and microwave plasma curing according to some embodiments herein. The process may employ a precursor and one or more process gases including a co-reactant. The one or more process gases may be continuously provided to the reactor chamber at a constant flow rate. Precursor pulses and RF pulses may be applied sequentially in the deposition station. The deposition station may be maintained at a consistent pressure and temperature during the gap-fill deposition. After completion of a deposition step, the wafer may be transferred to a treatment station to undergo a treatment process (e.g., thermal anneal and microwave plasma cure). In some embodiments, one or more process gases can be provided to the treatment station continuously while an anneal pressure and anneal temperature are maintained. In some embodiments, process gases used in a treatment station may comprise, for example, Ar, O₂, H₂, N₂, NH₃, He, and/or any combination of thereof. Ultraviolet light may be provided in the treatment station during the treatment process by way of a microwave plasma. The ALD deposition-treatment cycle may be repeated any number of times to achieve desired film quality/thickness. In some embodiments, the ALD process and the treatment process may be employed simultaneously, wherein the ALD process is performed on a first substrate while the treatment process may be performed on a second substrate. In a dual chamber module, such as that illustrated in FIG. 7C, the first substrate and the second substrate can be exchanged between RC1 and RC2 repeatedly until a desired film quality is achieved on both substrates.

FIG. 11B illustrates an example gap-fill method using a repeated cycle of a vapor deposition process, such as CVD, and treatment according to some embodiments herein. In contrast to the ALD method, for CVD, the precursor and RF power may be applied concurrently. The treatment process may be substantially similar to or the same as the one employed after the ALD process. The CVD deposition-treatment cycle may be repeated any number of times to achieve a desired film quality/thickness. In some embodiments, the CVD process and the treatment process may be employed simultaneously, wherein the CVD process is performed on a first substrate while the treatment process may be performed on a second substrate. In some embodiments, the anneal and microwave plasma treatment may be performed intermittently, such that the anneal and microwave plasma treatment is performed for every 1 nm to 5 nm of deposited film thickness or for every 5 nm to 100 nm of deposited film thickness. In some cases, when the film thickness is greater than about 100 nm, voids may form upon thermal annealing and microwave plasma curing.

FIG. 11C illustrates an example gap-fill method using repeated cycle of ALD and annealing with a microwave plasma cure according to some embodiments herein. As with the ALD process of FIG. 11A, precursor pulses and RF pulses may be applied sequentially. In some embodiments, the microwave plasma cure may create additional bonds in the remaining film. In some embodiments, the microwave plasma cure comprises continuously providing one or more process gases to the station and microwave pulsing. In some embodiments, the process gases flowed into the station during the deposition process may be different than or the same as the process gases flowed into the station during the microwave plasma cure. In some embodiments, multiple process gases may be used. In some embodiments, only one process gas may be used. For example, one process gas may be used during deposition, while another process gas or gases may be used for plasma curing, purging, and so forth. In some embodiments, the pressure in the treatment RC may be about the same as the pressure in the deposition RC.

FIG. 11D depicts an example CVD version of the process depicted in FIG. 11C As discussed above in relation to FIG. 11B, the CVD process differs principally from the ALD process in that the precursor and RF power may be applied concurrently.

### Rapid Thermal Anneal

In some embodiments, the temperature difference between gap-fill stations in the multi-process chamber module described herein may be significant. For example, the flowable deposition stations may be maintained at less than 300° C. and the cyclic treatment stations may be maintained at about 450° C. In some embodiments, this may require complex hardware design. Additionally, in some embodiments, process times may be extended as the entire wafer must be heated and cooled for each treatment step.

In some embodiments, the temperature change between the deposition and microwave plasma cure has a negligible effect on chemical reactions, so there may be no need to minimize this time to improve chemical reactions. In some embodiments, for post high temperature annealing, Rapid Thermal Anneal may be applicable, but not necessary for only one time post annealing.

In some embodiments, the use of a cyclic Rapid Thermal Anneal (RTA) may be used as an alternative to the use of the thermal treatment, as described above. In this case, the wafer is heated rapidly by exposure to infrared (IR) radiation, which may cure the gap-fill material improving its properties and quality. RTA exposure times can be in the range of about 0.1 sec to about 10 sec and allow for relatively higher temperatures to be used as only the top surface of the wafer is heated. For example, in some embodiments, the RTA exposure time may be about 0.1 sec, about 0.2 sec, about 0.3 sec, about 0.4 sec, about 0.5 sec, about 0.6 sec, about 0.7 sec, about 0.8 sec, about 0.9 sec, about 1 sec, about 1.1 sec, about 1.2 sec, about 1.3 sec, about 1.4 sec, about 1.5 sec, about 1.6 sec, about 1.7 sec, about 1.8 sec, about 1.9 sec, about 2 sec, about 2.1 sec, about 2.2 sec, about 2.3 sec, about 2.4 sec, about 2.5 sec, about 2.6 sec, about 2.7 sec, about 2.8 sec, about 2.9 sec, about 3 sec, about 3.1 sec, about 3.2 sec, about 3.3 sec, about 3.4 sec, about 3.5 sec, about 3.6 sec, about 3.7 sec, about 3.8 sec, about 3.9 sec, about 4 sec, about 4.1 sec, about 4.2 sec, about 4.3 sec, about 4.4 sec, about 4.5 sec, about 4.6 sec, about 4.7 sec, about 4.8 sec, about 4.9 sec, about 5 sec, about 5.1 sec, about 5.2 sec, about 5.3 sec, about 5.4 sec, about 5.5 sec, about 5.6 sec, about 5.7 sec, about 5.8 sec, about 5.9 sec, about 6 sec, about 6.1 sec, about 6.2 sec, about 6.3 sec, about 6.4 sec, about 6.5 sec, about 6.6 sec, about 6.7 sec, about 6.8 sec, about 6.9 sec, about 7 sec, about 7.1 sec, about 7.2 sec, about 7.3 sec, about 7.4 sec, about 7.5 sec, about 7.6 sec, about 7.7 sec, about 7.8 sec, about 7.9 sec, about 8 sec, about 8.1 sec, about 8.2 sec, about 8.3 sec, about 8.4 sec, about 8.5 sec, about 8.6 sec, about 8.7 sec, about 8.8 sec, about 8.9 sec, about 9 sec, about 9.1 sec, about 9.2 sec, about 9.3 sec, about 9.4 sec, about 9.5 sec, about 9.6 sec, about 9.7 sec, about 9.8 sec, about 9.9 sec, about 10 sec, or any value between any of the aforementioned values.

In some embodiments, the RTA may be performed at relatively higher temperatures than the thermal treatment/anneal discussed above. For example, in some embodiments, an RTA may be performed at a temperature between about 80° C. to about 1000° C. In some embodiments, the RTA may be performed at about 80° C., about 105° C., about 130° C., about 155° C., about 180° C., about 205° C., about 230° C., about 255° C., about 280° C., 300° C., about 325° C., about 350° C., about 375° C., about 400° C., about 425° C., about 450° C., about 475° C., about 500° C., about 525° C., about 550° C., about 575° C., about 600° C., about 625° C., about 650° C., about 675° C., about 700° C., about 725° C., about 750° C., about 775° C., about 800° C., about 825° C., about 850° C., about 875° C., about 900° C., about 925° C., about 950° C., about 975° C., about 1000° C., or any value between the aforementioned values. In some embodiments, a higher temperature RTA may correspond to a lower exposure time.

As such, in some embodiments herein, a cyclic RTA may be utilized for curing flowable gap-fill. In some embodiments, a cyclic RTA may prevent redeposition, which can be a problem in cyclic plasma treatments, while increasing throughput compared to a cyclic thermal treatment.

In some embodiments, in contrast to the multi-process chamber module apparatus and methods described above, during RTA, the substrate stage in the treatment station can be kept at the same temperature as the substrate stage in the deposition station, avoiding a temperature gap between treatments. As in the cyclic anneal, The RTA with IR-heating could be provided in a separate chamber to the flowable deposition, which requires wafer movement during each deposition-anneal cycle. However, in some embodiments, the RTA could be integrated in the deposition station itself to increase throughput. In some embodiments, using a single station may increase throughput and decrease the apparatus size. However, in some embodiments, when process gasses or desired process parameters (e.g., pressure) differ between the deposition station and thermal treatment, using a multi-station apparatus may be preferred.

In some embodiments, a deposition-RTA cycle may be repeated m number of times, wherein m is an integer. The value of m may depend on various process variables, including the growth rate of the flowable deposition process, on the volume of the gap structure to be filled, and whether the optional plasma cure is implemented. For example, in some embodiments, if a plasma cure is implemented, an RTA may be provided for every about 1 nm to about 5 nm of film growth. In some embodiments, if a plasma cure is not implemented, an RTA may be provided for every about 5 nm to about 100 nm of film growth.

As noted above, RTA substantially heats a top surface of wafer only. Thus, a temperature gap between stations is not required as it would be in multi-process chamber module conducting a flowable deposition and cyclic anneal. Furthermore, heating and cooling in RTA can be accelerated relative a cyclic anneal. The RTA approach avoids the redeposition effect observed in a cyclic plasma treatment and increases throughput compared to the cyclic thermal treatment.

### High-Temperature Curing

In some embodiments, a film (e.g., a SiCN film) deposited as described above may exhibit some undesirable properties. For example, there may still be voids or seams, a wet etch rate may be undesirably high or unstable, or a surface may be undesirably rough. In some embodiments, a high temperature cure can improve film quality. However, a single step high-temperature cure may result in film desorption at high temperatures. Thus, in some embodiments, an additional QCM can be used for high temperature curing after a cyclic deposition process. That is, by performing intermediate cyclic curing steps (e.g., thermal annealing and/or microwave plasma curing), it may be possible to perform a final high temperature cure with reduced risk of damage to the film.

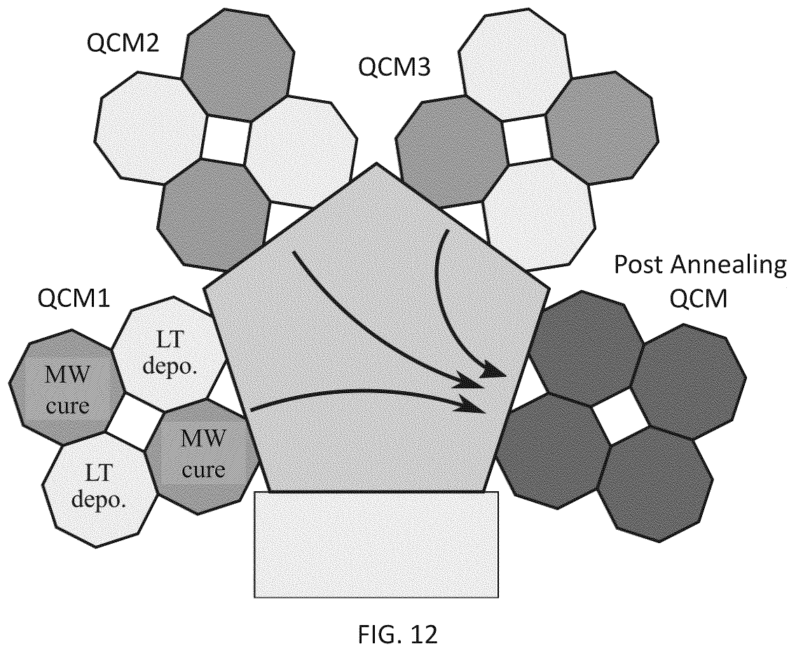

FIG. 12 depicts an example apparatus for performing deposition according to some embodiments herein. In FIG. 12, an apparatus has three process QCMs for cyclic deposition processes as described herein and has a fourth annealing QCM for high temperature annealing. After completing a cyclic deposition process, wafers may be transferred from the process QCMs to the annealing QCM for annealing.

While FIG. 12 shows an apparatus with a separate QCM for annealing, it will be appreciated that a QCM is not necessary. For example, the annealing chamber may have 1 station, 2 stations, 3 stations, 4 stations, 5 stations, 6 stations, or more.

### Additional Processes

As discussed herein, a flowable gap fill process can have a benefit of filling a gap without leaving a seam or void therein or with relatively small seams of voids therein. Unlike other gap fill process such as CVD or ALD in which a film is formed along the surface of the gap structure, a flowable process can utilize the flowability of a source material to fill a gap structure, which can result in a gap fill that is substantially seamless, void-free, or both.

In some embodiments, a flowable process may include supplying a flowable source gas, followed by supplying a reactant. In some embodiments, the reactant may be further activated by a power applied to the reaction space. For example, in some embodiments, in order to form a flowable SiN film, a flowable silicon-containing precursor may be supplied, followed by a nitrogen-containing reactant activated by RF power. In some embodiments, the silicon precursor may be a trisilylamine and the nitrogen-containing gas may be NH₃.

In some embodiments, to further control one or more film properties, a post-treatment process may be carried out. For example, in some embodiments, to precisely control a wet etch rate (WER) of a flowable SiN film in a gap, a thermal treatment (e.g., annealing), an RF plasma treatment, a UV treatment, and/or a vacuum UV (VUV) treatment may be carried out. In some embodiments, the thermal treatment can be effective in controlling a WER of the film within the bulk portion of the film but may not achieve a desired WER. In some embodiments, an RF plasma treatment can be effective in controlling a WER of the surface of a film but may not achieve a desired WER within the bulk portion of the film. In some embodiments, a VUV treatment can be effective in improving a WER of a film within the bulk portion of the film but may not achieve a desired WER of the film on the surface of the film. In order to resolve this matter, in some embodiments, a thermal treatment and an RF treatment can be carried out simultaneously. However, RF plasma treatment can damage the surface of a film.

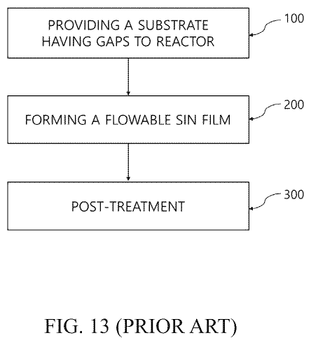

FIG. 13 illustrates a conventional flowable SiN process. In FIG. 13, the method of processing a substrate comprises providing a substrate having gaps therein to a reactor 100, followed by forming a flowable SiN film 200 by supplying a silicon-containing precursor with fluidity and a nitrogen-containing gas as a reactant. In another embodiment, the reactant may be further activated by RF power. The formed SiN film may further comprise carbon (C), hydrogen (H), or both (e.g., SiCN, SiHCN) when using a silicon precursor comprising N, H and/or C in the molecular structure. In some embodiments, an oxygen-containing reactant can be supplied to convert a SiN film into at least one of a SiO, SiON and/or SiOCN film.

In some embodiments, the silicon precursor may comprise an oligomeric silicon precursor. More specifically, the oligomeric silicon precursor may comprise trimer-trisilylamine (TSA) and a nitrogen-containing gas may comprise at least gas one selected from N₂, N₂O, NO₂, NH₃, NH₄, N₂H₂, N₂H₄, radicals thereof, and/or mixtures thereof.

When the molecular structure of the silicon precursor is too simple, for example, when the silicon precursor is a monomer or a single molecule, a vapor pressure thereof can be relatively high. When the vapor pressure is relatively high, the silicon precursor can be volatized relatively easily. As a result, the silicon precursor may lose flowability. Conversely, when the molecular structure of the silicon precursor comprise a complicated polymer, a molecular weight thereof can be large and the vapor pressure thereof can be relatively low, which can result in the flowability of the silicon precursor being too low. As a result, the efficiency may be lowered in a process that requires flowability above an appropriate level.

In some embodiments, the formation of a SiN film may be carried out at about 100° C. or below, for example below 80° C. In some embodiments, the silicon precursor may be delivered to the reactor by a carrier gas. In some embodiments, the carrier gas may comprise, for example, argon (Ar). In some embodiments, the nitrogen-containing gas may be activated by RF power exerted into the reactor. In some embodiments, the intensity of RF power applied may be below about 200 W, for example from about 50 W to about 100 W. In some embodiments, the RF power may be applied for between about 30 seconds and about 100 seconds, for example from about 40 seconds to about 80 seconds. In some embodiments, the reactor pressure for forming a SiN film may be, for example, about 1200 Pa.

In some embodiments, in order to control a film property, a post-treatment 300 may be carried out as shown in FIG. 13. For instance, in some embodiments, a wet etch rate ratio (WERR) of the film may be lowered by the post-treatment. In some embodiments, the post-treatment may comprise at least one of thermal treatment, RF plasma treatment, ultraviolet (UV), and/or vacuum UV (VUV) treatment. In some embodiments, a lower WERR can be desirable. For example, in some embodiments, a target WERR can be from about 0.5 to about 1.0, for example about 0.85.

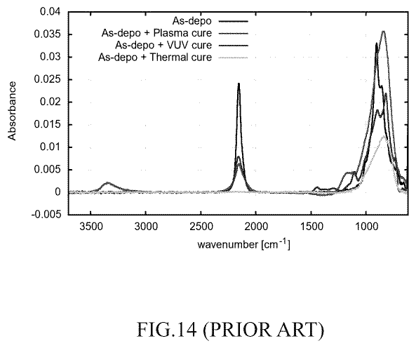

FIG. 14 illustrates Infrared (IR) spectra data showing a bonding structure of the flowable SiN film according to the post-treatment according to some embodiments herein and Table 1 shows a WERR of flowable SiN film according to the post-treatment according to some embodiments herein.

In FIG. 14 and Table 2, an as-deposited SiN film on which a post-treatment is not carried out shows high intensity of Si—H bonding and high WERR. The high WERR can result from the Si—H bonding. SiN films on which a post-treatment is carried out show lower WERR compared to that of as-deposited SiN film. However, a SiN film on which a VUV treatment was applied still has relatively high Si—H bonding and high WERR as compared to films treated with RF plasma or a thermal treatment. As shown in in Table 2, a SiN film with thermal treatment has relatively low Si—H bonding. However, the WERR of the thermally treated film can still have a WERR that is higher than desired (e.g., above a target WERR, for example above about 0.85). A SiN film on which a RF plasma treatment has strong Si—N bonding, but still has a WERR that is above the target WERR. In some embodiments, to further lower WERR, additional RF power may be applied. However, in some embodiments, an additional RF plasma application may reduce or eliminate the dangling bonding of the film structure, which can lead to oxidation when the film is exposed to the air.

TABLE 2
Example WERRs of flowable SiN films

| | | RF Plasma | VUV | Thermal |
|---|---|---|---|---|
| | As-Deposited | Treatment | Treatment | Treatment |
| WERR | >51.53 | 4.683 | >22.83 | 1.004 |

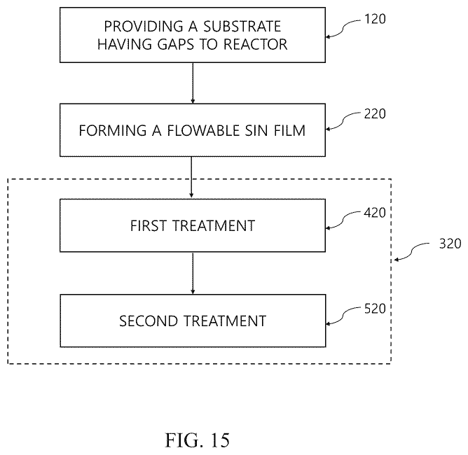

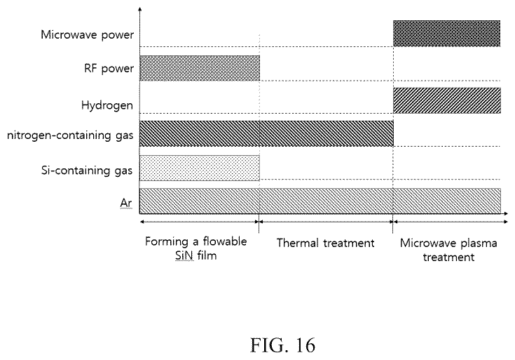

FIG. 15 illustrates a process flowchart for a flowable SiN gap fill process according to some embodiments the present disclosure, and FIG. 16 illustrates a timing graph for an exemplary flowable SiN gap fill process thereof.

In FIG. 15, a substrate having gaps is provided to the reactor 120. More specifically, in some embodiments, the substrate may be mounted onto a susceptor. In some embodiments, the susceptor can comprise a heating block to heat up the substrate to a process temperature. In some embodiments, after heating to the process temperature, a step of forming a flowable SiN film 220 may be carried out by supplying a silicon-containing precursor with fluidity and a nitrogen-containing gas as a reactant to the reactor. In some embodiments, the silicon-containing precursor may be an oligomeric precursor, for example a trimer-trisilylamine. In some embodiments, the nitrogen-containing gas can be at least one selected from N₂, N₂O, NO₂, NH₃, NH₄, N₂H₂, N₂H₄, radicals thereof, and/or mixtures thereof. In some embodiments, the formed film may be at least one of SiN, SiCN, SiHCN, and/or combinations thereof.

When the molecular structure of the silicon precursor is too simple, for example, when the silicon precursor is a monomer or a single molecule, a vapor pressure thereof can be high and thus the silicon precursor can be volatilized easily. Accordingly, the silicon precursor may lose flowability. When the molecular structure of the silicon precursor is a complicated polymer, a molecular weight thereof can be large and the vapor pressure thereof can be low. The flowability of a relatively high molecular weight silicon precursor may be too low, which can cause efficiency to be lowered in a process that requires at least a minimum flowability.

In some embodiments, the formation of a SiN film may be carried out at about 100° C. or below, for example below about 80° C. In some embodiments, the silicon precursor may be carried to the reactor by a carrier gas which can be, for example, Argon (Ar). In some embodiments, the nitrogen-containing gas may be activated by RF power exerted into the reactor. In some embodiments, the intensity of RF power applied may be below about 200 W, for example in a range of about 50 W to about 100 W, and the RF power may be applied for between about 30 seconds and about 100 seconds, for example about 40 seconds to about 80 seconds. In some embodiments, the reactor pressure for forming a SiN film can be from about 1,000 Pa to about 1,500 Pa.

As shown in FIG. 15, in some embodiments, a post-treatment step 320 can be carried out. In some embodiments, the post-treatment step may include a first treatment step 420 and a second treatment step 520. In some embodiments, the first treatment step 420 and the second treatment step 520 may comprise at least one of thermal treatment, microwave plasma treatment, RF plasma treatment, UV treatment, and VUV treatment, or a combination thereof. In some embodiments, one of the first treatment step 420 and the second treatment step 520 may comprise a microwave plasma treatment step.

FIG. 16 illustrates an example embodiment of a flowable SiN process.

In FIG. 16, a flowable SiN film is formed, followed by a thermal treatment as a first treatment step and a microwave plasma treatment step as a second treatment step.

In some embodiments, the microwave plasma can have low ion energy compared to the conventional RF plasma. In some embodiments, the use of a microwave plasma can have a technical advantage in that applying the microwave plasma may result in less damage to the film and can lower the WERR.

In some embodiments, the thermal treatment may be carried out at about 800° C. or below, for example from about 400° C. to about 600° C. In some embodiments, the thermal treatment can be carried out for from about 160 seconds to about 200 seconds. In some embodiments, during the thermal treatment, one or more inert gases such as, for example, Ar and N₂ can be supplied to the reactor. In some embodiments, the reactor pressure for the thermal treatment can be from about 1,000 Pa to about 1,500 Pa.

In some embodiments, the microwave plasma treatment may be carried out at about 200° C. or below, for example from about room temperature to about 180° C. In some embodiments, the microwave plasma treatment can be performed for from about 400 seconds to about 800 seconds. In some embodiments, during the microwave plasma treatment step, a hydrogen-containing gas can be supplied. The hydrogen-containing gas may be, for example, at least one of H₂, N₂H₂, N₂H₄, NH₃, NH₄, N₂—H₂ mixed gas, or a combination thereof. In some embodiments, the frequency of the microwave plasma may be about 2.53 GHz. In some embodiments, the intensity of the microwave plasma can be at or below about 100 W, for example between about 40 W and about 80 W. In some embodiments, the reactor pressure for the microwave can be from about 1 Pa to about 10 Pa.

FIG. 16 illustrates a thermal treatment as a first treatment step and a microwave plasma treatment as a second treatment step. However, it will be appreciated that the type of treatment(s) and the order of the treatment(s) are not limited to this particular combination or sequence. For example, the first treatment step and the second treatment step may comprise at least one of thermal treatment, microwave plasma treatment, RF plasma treatment, UV treatment, VUV treatment, and any combination thereof. According to some embodiments, at least one of the first treatment step and the second treatment step may be a microwave plasma treatment.

In some embodiments, the flowable SiN film gap fill, the thermal treatment, and the microwave plasma treatment may be carried out ex-situ. In some embodiments, a process can be carried out in a multi-reactor chamber in which the substrate is transferred from one reactor to another reactor to carry out sequentially the step of forming the SiN film, the first treatment step, and the second treatment step.

In some embodiments, a flowable SiN gap fill deposition process may be carried out in a first reactor, then the substrate may be transferred to a second reactor, and the thermal treatment can be carried out therein. In some embodiments, the substrate may be further transferred to a third reactor, and the microwave plasma treatment may be carried out therein. In some embodiments, the microwave plasma may be supplied to the reactor remotely. In some embodiments, substrate processing may be implemented in a multiple reactor chamber without breaking a vacuum among reactors.

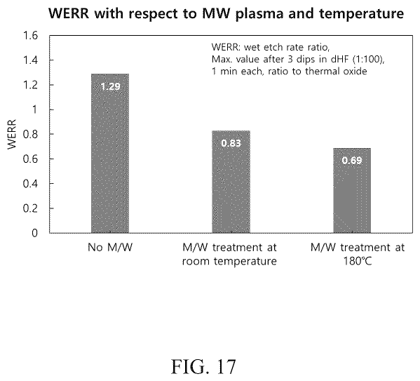

According to some embodiments, the WERR may be further lowered by controlling the temperature during the microwave plasma treatment step. As shown in FIG. 17, the WERR of the film can be lowered by raising the temperature. When the temperature is above about 25° C. (e.g., about room temperature), the WERR can be close to a target WERR (e.g., lower than 0.85). Processing at a higher temperature (e.g., about 180° C.), can further lower the WERR.

### Additional Embodiments

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

Indeed, although this invention has been disclosed in the context of certain embodiments and examples, it will be understood by those skilled in the art that the invention extends beyond the specifically disclosed embodiments to other alternative embodiments and/or uses of the invention and obvious modifications and equivalents thereof. In addition, while several variations of the embodiments of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the embodiments of the disclosed invention. Any methods disclosed herein need not be performed in the order recited. Thus, it is intended that the scope of the invention herein disclosed should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the invention is not to be limited to the particular forms or methods disclosed, but, to the contrary, the invention is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A method for flowable gap-fill deposition, the method comprising:
(a) placing a substrate in a first station;
(b) depositing a flowable material on the substrate in the first station by a vapor deposition process at a first temperature;
(c) placing the substrate in a second station;
(d) heating a surface of the substrate to a second temperature in the second station and exposing the substrate to a microwave plasma generated from a plasma gas source; and
repeating (a)-(d) in a cycle until a film of desired thickness is deposited on the substrate.

2. The method of claim 1, wherein the first temperature is less than 300° C.

3. The method of claim 1, wherein the second temperature is between 80° C. and 1000° C.

4. The method of claim 1, wherein the plasma gas source comprises at least one of Ar, H₂, N₂, or NH₃.

5. The method of claim 1, wherein the first station comprises an upper chamber and a lower chamber, and wherein the lower chamber comprises a shared intermediate space between the first station and the second station.

6. The method of claim 1, wherein the first station and the second station comprise a shared pressure system such that the first station and the second station are maintained at a common pressure during the cycle.

7. The method of claim 6, wherein the common pressure during the cycle is between 100 Pa and 4000 Pa.

8. The method of claim 1, wherein the first station comprises a first station heating unit configured to control a temperature of the first station independently of a temperature of the second station, and wherein the second station comprises a second station heating unit configured to control the temperature of the second station independently of the first station.

9. The method of claim 1, wherein the film comprises a SiCN, SiN, or SiHCN film, or combination thereof.

10. The method of claim 1, wherein the film fills at least 90% of a gap on the surface of the substrate, at least 95% of a gap on the surface of the substrate, at least 99% of a gap on the surface of the substrate, or at least 99.5% of a gap on the surface of the substrate.

11. The method of claim 1, further comprising introducing one or more process gasses into the first station during contacting the substrate in the first station, wherein the process gasses comprise Ar, He, N₂, H₂, NH₃, O₂, or a combination of one or more of the above.

12. The method of claim 1, further comprising, after a film of desired thickness is deposited on the substrate:
transferring the substrate to an annealing chamber; and
annealing the substrate at a third temperature, wherein the third temperature is higher than the first temperature and the second temperature.

13. The method of claim 1, wherein step (b) comprises depositing from about 1 nm to about 5 nm of film thickness.

14. The method of claim 1, wherein step (b) comprises depositing from about 5 nm to about 100 nm of film thickness.

15. A semiconductor processing apparatus comprising:
one or more process chambers, each process chamber comprising two or more stations, each station comprising an upper compartment and a lower compartment,
wherein the upper compartment is configured to contain a substrate during processing of the substrate;
wherein the lower compartment comprises a shared intermediate space between the two or more stations;
a first transfer system configured to move a substrate from a first process chamber to a second process chamber in a wafer handling chamber;
a second transfer system configured to move the substrate from a first station to a second station within the shared intermediate space of a process chamber;
a first heating unit configured to control a first station temperature independently of a second station temperature;
a pressure system comprising a pump and exhaust, the pressure system configured to maintain a common process chamber pressure in the two or more stations; and
a controller comprising a processor that provides instructions to the apparatus to control a cycle of:
(a) placing a substrate in a first station;
(b) depositing a flowable material on the substrate in the first station by a vapor deposition process at a first temperature, wherein the first temperature is less than 150° C.;
(c) after depositing the flowable material on the substrate, placing the first substrate in the second station;
(d) heating a surface of the substrate to a second temperature in the second station and exposing the substrate to a microwave plasma generated from a plasma gas source; and
repeating (a)-(d) in a cycle until a film of desired thickness is deposited on the substrate.

16. A method of processing a substrate having gaps, comprising:
providing a substrate to a reactor,
forming a SiN film by supplying a silicon-containing precursor with fluidity and a nitrogen-containing gas to the reactor; and
performing post-treatment for treating the SiN film,
wherein post-treatment comprises a first treatment step and a second treatment step.

17. The method of claim 16, wherein the nitrogen-containing gas is activated by applying a RF power to the reactor.

18. The method of claim 17, wherein an intensity of the RF power is about 200 W or below.

19. The method of claim 16, wherein the nitrogen-containing gas comprises at least one of N₂, N₂O, NO₂, NH₃, NH₄, N₂H₂, N₂H₄, radicals thereof, or mixtures thereof.

20. The method of claim 17, wherein the silicon-containing precursor comprises an oligomeric precursor.

21. The method of claim 20, wherein the silicon-containing precursor comprises trimer-tri silylamine.

22. The method of claim 16, wherein the forming the SiN film is carried out at about 100° C. or below.

23. The method of claim 16, wherein the first treatment step and the second treatment step comprise at least one of thermal treatment, microwave plasma treatment, RF plasma treatment, UV treatment, VUV treatment and any combination thereof.

24. The method of claim 23, wherein at least one of the first treatment step or the second treatment step comprises a microwave plasma treatment.

25. The method of claim 24, wherein the first treatment step comprises a thermal treatment and the second treatment step comprises a microwave plasma treatment.

26. The method of claim 25, wherein the thermal treatment is carried out at about 800° C. or below.

27. The method of claim 25, wherein the microwave plasma treatment is carried out at about 200° C. or below.

28. The method of claim 25, wherein an intensity of the microwave plasma is 100 W or below.

29. The method of claim 25, wherein a hydrogen-containing gas is supplied to the reactor during the microwave plasma treatment.

30. The method of claim 29, wherein the hydrogen-containing gas is at least one of H₂, N₂H₂, N₂H₄, NH₃, NH₄, N₂—H₂ mixing gas, or a mixture thereof.

31. The method of claim 16, wherein a wet etch rate ratio of the SiN film is lower than 0.85.

32. The method of claim 25, wherein the forming the SiN film, the thermal treatment, and the microwave plasma treatment are carried out ex-situ.

33. The method of claim 24, wherein the microwave plasma is provided to the reactor remotely.

34. The method of claim 16, wherein the method is carried out in a multi-reactor chamber,
the multi-reactor chamber comprising a first reactor, a second reactor, and a third reactor,
wherein the substrate is transferred from the first reactor to the second reactor,
wherein the substrate is transferred from the second reactor to the third reactor,
and wherein the forming the SiN film is carried out in the first reactor, the first treatment step is carried out in the second reactor, and the second treatment step is carried out in the third reactor.
